(19) United States
(12) Patent Application Publication
(10) Pub. No.: US 2023/0305115 A1
(43) Pub. Date: Sep. 28, 2023

(54) LIDAR SYSTEM COMMUNICATION USING DATA ENCODING FOR COMMUNICATING POINT CLOUD DATA

(71) Applicant: Innovusion, Inc., Sunnyvale, CA (US)

(72) Inventors: Gang Zhou, San Jose, CA (US); Haosen Wang, Sunnyvale, CA (US); Jian Wen, Fremont, CA (US); Zheng Yang, Los Altos, CA (US)

(73) Assignee: Innovusion, Inc., Sunnyvale, CA (US)

(21) Appl. No.: 18/126,069

(22) Filed: Mar. 24, 2023

Related U.S. Application Data
(60) Provisional application No. 63/324,012, filed on Mar. 25, 2022.

(51) Int. Cl. G01S 7/481; G01S 17/931; G01S 17/89; H03M 7/30

(52) U.S. Cl. CPC G01S 7/4817; G01S 7/4814; G01S 17/931; G01S 17/89; H03M 7/70; H03M 7/3068

(57) ABSTRACT

Light detection and ranging (LiDAR) systems use light pulses to create an image or point cloud of an environment. This LiDAR system and method having data encoding and compression improves the efficiency and communication reliability of point cloud data using data encoding and compression. After receiving return light pulse reflected by an object in the FOV, the system converts the detected optical signal data into raw data for the purpose of generating trigger data, encoder data, and time synchronization data from the raw data. The system further configures output data in a compressed format using the least amount of bits to carry the same amount of information defining point cloud data describing an external environment and the computational load is reduced. The compressed format comprises a data set for one baseline channel and differential channel data for one or more channels based upon the baseline channel.

### CROSS-REFERENCE TO RELATED APPLICATIONS

This application claims priority to U.S. Provisional Patent Application Ser. No. 63/324,012, filed Mar. 25, 2022, entitled “LIDAR SYSTEM COMMUNICATION USING EFFECTIVE DATA FORMATTING OF THE POINT CLOUD,” the content of which is hereby incorporated by reference in its entirety for all purposes.

### FIELD OF THE TECHNOLOGY

This disclosure relates generally to light detection and ranging by a LiDAR system and, more particularly, to effective communication of point cloud data using data encoding and compression.

### BACKGROUND

Light detection and ranging (LiDAR) systems use light pulses to create an image or point cloud of the external environment. A LiDAR system may be a scanning or non-scanning system. Some typical scanning LiDAR systems include a light source, a light transmitter, a light steering system, and a light detector. The light source generates a light beam that is directed by the light steering system in particular directions when being transmitted from the LiDAR system. When a transmitted light beam is scattered or reflected by an object, a portion of the scattered or reflected light returns to the LiDAR system to form a return light pulse. The light detector detects the return light pulse. Using the difference between the time that the return light pulse is detected and the time that a corresponding light pulse in the light beam is transmitted, the LiDAR system can determine the distance to the object based on the speed of light. This technique of determining the distance is referred to as the time-of-flight (ToF) technique. The light steering system can direct light beams along different paths to allow the LiDAR system to scan the surrounding environment and produce images or point clouds. A typical non-scanning LiDAR system illuminate an entire field-of-view (FOV) rather than scanning through the FOV. An example of the non-scanning LiDAR system is a flash LiDAR, which can also use the ToF technique to measure the distance to an object. LiDAR systems can also use techniques other than time-of-flight and scanning to measure the surrounding environment.

### SUMMARY

Embodiments of a system and method for LiDAR having data encoding and compression are provided. It should be appreciated that the present embodiment can be implemented in numerous ways, such as a process, an apparatus, a system, a device, or a method. Several embodiments are described below.

In some embodiments, the method of data encoding and compression within a LiDAR system is provided. In particular, the method includes steering one or more beams of light using a plurality of reflective facets of the polygon mirror to scan a Field-Of-View (FOV) in a first direction. The method further includes steering the one or more beams of light using a galvanometer mirror to scan the FOV in a second direction. After return light pulses are reflected by one or more objects in the FOV, the method includes receiving detection data from an optical detector of the scanning system, wherein the detection data is associated with the return light pulse. The method includes decoding the detection data into raw data and configuring output data based on the raw data, trigger data, encoder data, and time synchronization data. The output data have a compressed format including a data set for one baseline channel and differential channel data for one or more channels based upon the baseline channel.

In some embodiments, the compressed output data can be sent in blocks, wherein each block corresponds to one laser firing and contains received data points from each one of the one or more channels. In some examples, the output data starts with a block header followed by data points of the point cloud. Representation of the output data may comprise the use of a spherical coordinate system. Further, the method of data encoding and compression within a LiDAR system includes transmitting the trigger data to one or more sources of light to control emission timing of the one or more beams of light. The method also includes receiving the encoder data from the optical steering mechanism based on encoder position data provided by the galvanometer mirror and the polygon mirror. In some embodiments, the output data and the time synchronization data are transmitted to external sources for further data processing.

In some embodiments, the LiDAR system having data encoding and compression is provided. In particular, the LiDAR system includes a laser source that supplies a plurality of light pulses to a optical steering mechanism, wherein the optical steering mechanism directs the plurality of light pulses in accordance with the FOV. In some examples, the optical steering mechanism comprises a mirror motor galvanometer for vertical scanning and a rotatable polygon mirror for horizontal scanning. The LiDAR system further includes an encoder/decoder processing agent coupled to receive detection data to transform the detection data into raw data and configure output data from the raw data, the trigger data, the encoder data, and the time synchronization data. In some embodiments, the output data is in a compressed format including a data set for one baseline channel and differential channel data for one or more channels based upon the baseline channel. Accordingly, the point cloud output data can be sent in blocks, wherein each block corresponds to one laser firing and contains received data points from each one of the one or more channels. In some examples, the output data starts with a block header followed by data points of the point cloud. Representation of point cloud output data may comprise the use of a spherical coordinate system. The system may further include a controller coupled to receive data from the encoder/decoder processing agent. The controller couples to the optical steering mechanism and the laser source to coordinate movement speed of the integrated mirror motor galvanometer and the rotatable polygon mirror with the plurality of light pulses supplied by the laser source.

In some embodiments, a tangible, non-transitory, computer-readable media having instructions whereupon which, when executed by a processor, cause the processor to perform the data encoding and compression method described herein. In particular, the method includes steering one or more beams of light using a plurality of reflective facets of the polygon mirror to scan a Field-Of-View (FOV) in a first direction. The method further includes steering the one or more beams of light using a galvanometer mirror to scan the FOV in a second direction. After return light pulses are reflected by one or more objects in the FOV, the method includes receiving detection data from an optical detector of the scanning system, wherein the detection data is associated with the return light pulses. The method includes decoding the detection data into raw data and configure output data from the raw data, trigger data, encoder data, and time synchronization data. The output data have a compressed format including a data set for one baseline channel and differential channel data for one or more channels based upon the baseline channel. In some embodiments, the point cloud output data can be sent in blocks, wherein each block corresponds to one laser firing and contains received data points from each one of the one or more channels. In some examples, the output data starts with a block header followed by data points of the point cloud. Representation of point cloud output data may comprise the use of a spherical coordinate system. Further, the method of data encoding and compression within a LiDAR system includes transmitting the trigger data to one or more sources of light to control emission timing of the one or more beams of light. The method also includes transmitting the encoder data to the optical steering mechanism for encoding the galvanometer mirror and the polygon mirror.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The present application can be best understood by reference to the embodiments described below taken in conjunction with the accompanying drawing figures, in which like parts may be referred to by like numerals.

FIG. 1 illustrates one or more example LiDAR systems disposed or included in a motor vehicle.

FIG. 2 is a block diagram illustrating interactions between an example LiDAR system and multiple other systems including a vehicle perception and planning system, according to some embodiments.

FIG. 3A is a block diagram illustrating an example LiDAR system, according to some embodiments.

FIG. 3B is a block diagram illustrating an example of the control circuitry of the LiDAR system of FIG. 3A, in accordance with some embodiments.

FIG. 4A is an example of the formats of trigger data, encoder data, raw data, and time synchronization data used in the LiDAR system of FIGS. 3A-3B, in accordance with some embodiments.

FIG. 4B is an example of a block header format of the output data configured by the LiDAR system of FIGS. 3A-3B, in accordance with some embodiments.

FIG. 4C is a pulse peak value diagram illustrating peak position and pulse width associated with the return light pulses received by the LiDAR system of FIGS. 3A-3B, in accordance with some embodiments.

FIG. 4D is an example of a data point format of the output data configured by the LiDAR system of FIGS. 3A-3B, in accordance with some embodiments.

FIG. 5 is a flow diagram of a method for data encoding and compression of a LiDAR system of FIGS. 3A-3B, in accordance with some embodiments.

FIG. 6 is a block diagram illustrating an example fiber-based laser source, in accordance with some examples.

FIGS. 7A-7C illustrate an example LiDAR system using pulse signals to measure distances to objects disposed in a field-of-view (FOV), in accordance with some examples.

FIG. 8 displays an illustration showing an example of a computing device which may implement the examples described herein.

### DETAILED DESCRIPTION

To provide a more thorough understanding of various embodiments of the present invention, the following description sets forth numerous specific details, such as specific configurations, parameters, examples, and the like. It should be recognized, however, that such description is not intended as a limitation on the scope of the present invention but is intended to provide a better description of the exemplary embodiments.

Throughout the specification and claims, the following terms take the meanings explicitly associated herein, unless the context clearly dictates otherwise:

The phrase “in one embodiment” as used herein does not necessarily refer to the same embodiment, though it may. Thus, as described below, various embodiments of the disclosure may be readily combined, without departing from the scope or spirit of the invention.

As used herein, the term “or” is an inclusive “or” operator and is equivalent to the term “and/or,” unless the context clearly dictates otherwise.

The term “based on” is not exclusive and allows for being based on additional factors not described unless the context clearly dictates otherwise.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously. Within the context of a networked environment where two or more components or devices are able to exchange data, the terms “coupled to” and “coupled with” are also used to mean “communicatively coupled with”, possibly via one or more intermediary devices. The components or devices can be optical, mechanical, and/or electrical devices.

Although the following description uses terms “first,” “second,” etc. to describe various elements, these elements should not be limited by the terms. These terms are only used to distinguish one element from another. For example, a first sensor could be termed a second sensor and, similarly, a second sensor could be termed a first sensor, without departing from the scope of the various described examples. The first sensor and the second sensor can both be sensors and, in some cases, can be separate and different sensors. The first direction of steering the one or more beams of light using a plurality of reflective facets of the polygon mirror to scan the FOV could be termed a second direction of steering the one or more beams of light. Additionally, throughout the specification, the meaning of “a”, “an”, and “the” includes plural references, and the meaning of “in” includes “in” and “on.”

Although some of the various embodiments presented herein constitute a single combination of inventive elements, it should be appreciated that the inventive subject matter is considered to include all possible combinations of the disclosed elements. As such, if one embodiment comprises elements A, B, and C, and another embodiment comprises elements B and D, then the inventive subject matter is also considered to include other remaining combinations of A, B, C, or D, even if not explicitly discussed herein. Further, the transitional term “comprising” means to have as parts or members, or to be those parts or members. As used herein, the transitional term “comprising” is inclusive or open-ended and does not exclude additional, unrecited elements or method steps.

As used in the description herein and throughout the claims that follow, when a system, engine, server, device, module, or other computing element is described as being configured to perform or execute functions on data in a memory, the meaning of “configured to” or “programmed to” is defined as one or more processors or cores of the computing element being programmed by a set of software instructions stored in the memory of the computing element to execute the set of functions on target data or data objects stored in the memory.

It should be noted that any language directed to a computer should be read to include any suitable combination of computing devices or network platforms, including servers, interfaces, systems, databases, agents, peers, engines, controllers, modules, or other types of computing devices operating individually or collectively. One should appreciate the computing devices comprise a processor configured to execute software instructions stored on a tangible, non-transitory computer readable storage medium (e.g., hard drive, FPGA, PLA, solid state drive, RAM, flash, ROM, or any other volatile or non-volatile storage devices). The software instructions configure or program the computing device to provide the roles, responsibilities, or other functionality as discussed below with respect to the disclosed apparatus. Further, the disclosed technologies can be embodied as a computer program product that includes a non-transitory computer readable medium storing the software instructions that causes a processor to execute the disclosed steps associated with implementations of computer-based algorithms, processes, methods, or other instructions. In some embodiments, the various servers, systems, databases, or interfaces exchange data using standardized protocols or algorithms, possibly based on HTTP, HTTPS, AES, public-private key exchanges, web service APIs, known financial transaction protocols, or other electronic information exchanging methods. Data exchanges among devices can be conducted over a packet-switched network, the Internet, LAN, WAN, VPN, or other type of packet switched network; a circuit switched network; cell switched network; or other type of network.

Current LiDAR systems use light pulses to create an image or a 3D point cloud of the external environment. In some examples, scanning LiDAR systems include a light source, a light transmitter, an optical steering mechanism, and a light detector. The light source generates a light beam that is directed by the optical steering mechanism in particular directions when being transmitted from the LiDAR system. When a transmitted light beam is scattered or reflected by an object, a portion of the scattered or reflected light returns to the LiDAR system to form a return light pulse. The light detector detects the return light pulse. Using the difference between the time that the return light pulse is detected and the time that a corresponding light pulse in the light beam is transmitted, the LiDAR system determines the distance to the object based on the speed of light. This data relating to the image or the 3D point cloud of the external environment (also referred to as the point cloud data or the LiDAR system output data) can be delivered to a vehicle perception and planning system and various other external systems, including intelligent infrastructure systems, and other vehicles for further processing and vehicular control.

Current and past versions of the data format of the LiDAR system output data associated with the image or point cloud of the external environment require a large number of bits; and thereby, these data formatting methods cause the LiDAR system to have low processing and communication efficiency. The LiDAR system disclosed herein, having data encoding and compression, reduces the number of bits, or uses the least number of bits, in the output data to carry the same or similar amount of information sufficient to define the image or point cloud of the external environment. Advantageously, the computational load is also reduced. This is especially helpful when the computational resources are limited in the LiDAR system or a vehicle onboard system to which the LiDAR system is connected. Less computational requirements also reduce communication bandwidth requirements and power consumption, which can be important for battery-powered vehicles.

Embodiments of present invention are described below. In various embodiments of the present invention, the method of data encoding and compression within a LiDAR system is provided. In particular, the method includes steering one or more beams of light using a plurality of reflective facets of the polygon mirror to scan a Field-Of-View (FOV) in a first direction. The method includes steering the one or more beams of light using a galvanometer mirror to scan the FOV in a second direction. After a return light pulse is reflected by an object in the FOV, the method includes receiving detection data from an optical detector of the scanning system, wherein the detection data is associated with the return light pulse. The method includes decoding the detection data into raw data and configuring output data from the raw data, trigger data, encoder data, and time synchronization data. The output data having a compressed format include a data set for one baseline channel and differential channel data for one or more channels based upon the baseline channel. In some embodiments, the point cloud output data can be sent in blocks, wherein each block corresponds to one laser firing and contains received data points from each one of the one or more channels. In some examples, the output data starts with a block header followed by data points of the point cloud. Representation of point cloud output data may comprise the use of a spherical coordinate system. Further, the method of data encoding and compression within a LiDAR system includes transmitting the trigger data to one or more sources of light to control emission timing of the one or more beams of light. The method also includes receiving the encoder data from the optical steering mechanism based on position encoders of the galvanometer mirror and the polygon mirror. In some embodiments, the output data and the time synchronization data are transmitted to external sources for further data processing.

In some embodiments, the LiDAR system having data encoding and compression is provided. In particular, the LiDAR system includes a laser source that supplies a plurality of light pulses to a optical steering mechanism, wherein the optical steering mechanism directs the plurality of light pulses in accordance with the FOV. In some examples, the optical steering mechanism comprises a mirror motor galvanometer for vertical motion scanning and a rotatable polygon mirror for horizontal motion scanning. The LiDAR system further includes an encoder/decoder processing agent coupled to receive detection data to transform the detection data into raw data and configure output data from the raw data, trigger data, encoder data, and time synchronization data. In some embodiments, the output data is in a compressed format including a data set for one baseline channel and differential channel data for one or more channels based upon the baseline channel. Accordingly, the point cloud output data can be sent in blocks, wherein each block corresponds to one laser firing and contains received data points from each one of the one or more channels. In some examples, the output data starts with a block header followed by data points of the point cloud. Representation of point cloud output data may comprise the use of a spherical coordinate system. The system may further include a controller coupled to receive data from the encoder/decoder processing agent. The controller couples to the optical steering mechanism and the laser source to coordinate movement speed of the integrated mirror motor galvanometer and the rotatable polygon mirror with the plurality of light pulses supplied by the laser source.

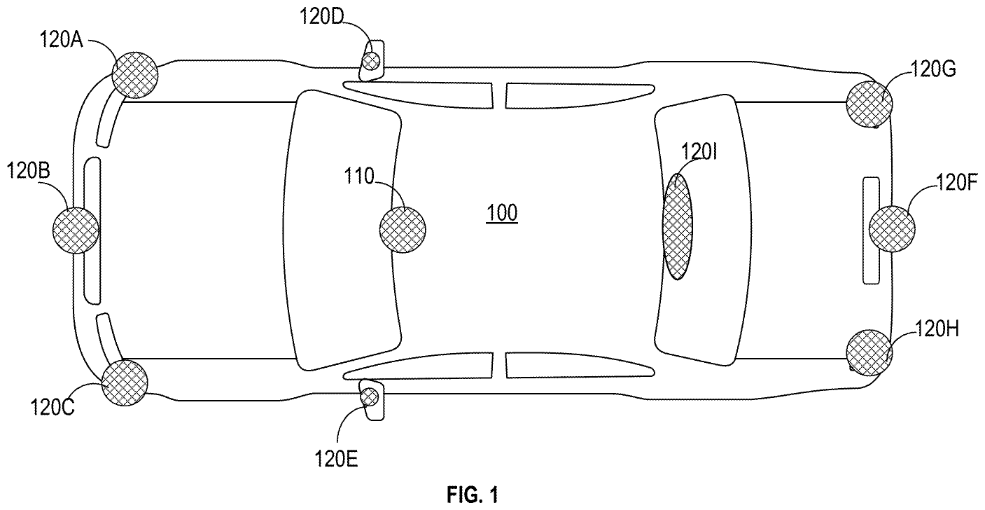

FIG. 1 illustrates one or more example LiDAR systems 110 disposed or included in a motor vehicle 100. Vehicle 100 can be a car, a sport utility vehicle (SUV), a truck, a train, a wagon, a bicycle, a motorcycle, a tricycle, a bus, a mobility scooter, a tram, a ship, a boat, an underwater vehicle, an airplane, a helicopter, a unmanned aviation vehicle (UAV), a spacecraft, etc. Motor vehicle 100 can be a vehicle having any automated level. For example, motor vehicle 100 can be a partially automated vehicle, a highly automated vehicle, a fully automated vehicle, or a driverless vehicle. A partially automated vehicle can perform some driving functions without a human driver's intervention. For example, a partially automated vehicle can perform blind-spot monitoring, lane keeping and/or lane changing operations, automated emergency braking, smart cruising and/or traffic following, or the like. Certain operations of a partially automated vehicle may be limited to specific applications or driving scenarios (e.g., limited to only freeway driving). A highly automated vehicle can generally perform all operations of a partially automated vehicle but with less limitations. A highly automated vehicle can also detect its own limits in operating the vehicle and ask the driver to take over the control of the vehicle when necessary. A fully automated vehicle can perform all vehicle operations without a driver's intervention but can also detect its own limits and ask the driver to take over when necessary. A driverless vehicle can operate on its own without any driver intervention.

In typical configurations, motor vehicle 100 comprises one or more LiDAR systems 110 and 120A-120I. Each of LiDAR systems 110 and 120A-120I can be a scanning-based LiDAR system and/or a non-scanning LiDAR system (e.g., a flash LiDAR). A scanning-based LiDAR system scans one or more light beams in one or more directions (e.g., horizontal and vertical directions) to detect objects in a field-of-view (FOV). A non-scanning based LiDAR system transmits laser light to illuminate an FOV without scanning. For example, a flash LiDAR is a type of non-scanning based LiDAR system. A flash LiDAR can transmit laser light to simultaneously illuminate an FOV using a single light pulse or light shot.

A LiDAR system is a frequently-used sensor of a vehicle that is at least partially automated. In one embodiment, as shown in FIG. 1, motor vehicle 100 may include a single LiDAR system 110 (e.g., without LiDAR systems 120A-120I) disposed at the highest position of the vehicle (e.g., at the vehicle roof). Disposing LiDAR system 110 at the vehicle roof facilitates a 360-degree scanning around vehicle 100. In some other embodiments, motor vehicle 100 can include multiple LiDAR systems, including two or more of systems 110 and/or 120A-120I. As shown in FIG. 1, in one embodiment, multiple LiDAR systems 110 and/or 120A-120I are attached to vehicle 100 at different locations of the vehicle. For example, LiDAR system 120A is attached to vehicle 100 at the front right corner; LiDAR system 120B is attached to vehicle 100 at the front center position; LiDAR system 120C is attached to vehicle 100 at the front left corner; LiDAR system 120D is attached to vehicle 100 at the right-side rear view mirror; LiDAR system 120E is attached to vehicle 100 at the left-side rear view mirror; LiDAR system 120F is attached to vehicle 100 at the back center position; LiDAR system 120G is attached to vehicle 100 at the back right corner; LiDAR system 120H is attached to vehicle 100 at the back left corner; and/or LiDAR system 120I is attached to vehicle 100 at the center towards the backend (e.g., back end of the vehicle roof). It is understood that one or more LiDAR systems can be distributed and attached to a vehicle in any desired manner and FIG. 1 only illustrates one embodiment. As another example, LiDAR systems 120D and 120E may be attached to the B-pillars of vehicle 100 instead of the rear-view mirrors. As another example, LiDAR system 120B may be attached to the windshield of vehicle 100 instead of the front bumper.

In some embodiments, LiDAR systems 110 and 120A-120I are independent LiDAR systems having their own respective laser sources, control electronics, transmitters, receivers, and/or steering mechanisms. In other embodiments, some of LiDAR systems 110 and 120A-120I can share one or more components, thereby forming a distributed sensor system. In one example, optical fibers are used to deliver laser light from a centralized laser source to all LiDAR systems. For instance, system 110 (or another system that is centrally positioned or positioned anywhere inside the vehicle 100) includes a light source, a transmitter, and a light detector, but have no steering mechanisms. System 110 may distribute transmission light to each of systems 120A-120I. The transmission light may be distributed via optical fibers. Optical connectors can be used to couple the optical fibers to each of system 110 and 120A-120I. In some examples, one or more of systems 120A-120I include steering mechanisms but no light sources, transmitters, or light detectors. An optical steering mechanism may include one or more moveable mirrors such as one or more polygon mirrors, one or more single plane mirrors, one or more multi-plane mirrors, or the like. Embodiments of the light source, transmitter, optical steering mechanism, and light detector are described in more detail below. Through the steering mechanisms, one or more of systems 120A-120I scan light into one or more respective FOVs and receive corresponding return light. The return light is formed by scattering or reflecting the transmission light by one or more objects in the FOVs. Systems 120A-120I may also include collection lens and/or other optics to focus and/or direct the return light into optical fibers, which deliver the received return light to system 110. System 110 includes one or more light detectors for detecting the received return light. In some examples, system 110 is disposed inside a vehicle such that it is in a temperature-controlled environment, while one or more systems 120A-120I may be at least partially exposed to the external environment.

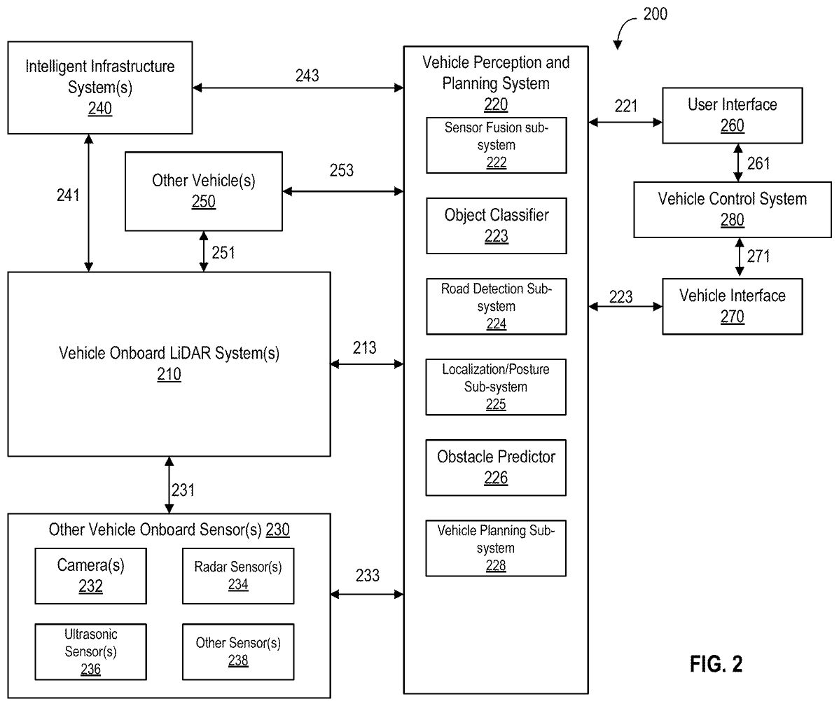

FIG. 2 is a block diagram 200 illustrating interactions between vehicle onboard LiDAR system(s) 210 and multiple other systems including a vehicle perception and planning system 220. LiDAR system(s) 210 can be mounted on or integrated to a vehicle. LiDAR system(s) 210 include sensor(s) that scan laser light to the surrounding environment to measure the distance, angle, and/or velocity of objects. Based on the scattered light that returned to LiDAR system(s) 210, it can generate sensor data (e.g., image data or 3D point cloud data) representing the perceived external environment.

LiDAR system(s) 210 can include one or more of short-range LiDAR sensors, medium-range LiDAR sensors, and long-range LiDAR sensors. A short-range LiDAR sensor measures objects located up to about 20-50 meters from the LiDAR sensor. Short-range LiDAR sensors can be used for, e.g., monitoring nearby moving objects (e.g., pedestrians crossing street in a school zone), parking assistance applications, or the like. A medium-range LiDAR sensor measures objects located up to about 70-200 meters from the LiDAR sensor. Medium-range LiDAR sensors can be used for, e.g., monitoring road intersections, assistance for merging onto or leaving a freeway, or the like. A long-range LiDAR sensor measures objects located up to about 200 meters and beyond. Long-range LiDAR sensors are typically used when a vehicle is travelling at a high speed (e.g., on a freeway), such that the vehicle's control systems may only have a few seconds (e.g., 6-8 seconds) to respond to any situations detected by the LiDAR sensor. As shown in FIG. 2, in one embodiment, the LiDAR sensor data can be provided to vehicle perception and planning system 220 via a communication path 213 for further processing and controlling the vehicle operations. Communication path 213 can be any wired or wireless communication links that can transfer data.

With reference still to FIG. 2, in some embodiments, other vehicle onboard sensor(s) 230 are configured to provide additional sensor data separately or together with LiDAR system(s) 210. Other vehicle onboard sensors 230 may include, for example, one or more camera(s) 232, one or more radar(s) 234, one or more ultrasonic sensor(s) 236, and/or other sensor(s) 238. Camera(s) 232 can take images and/or videos of the external environment of a vehicle. Camera(s) 232 can take, for example, high-definition (HD) videos having millions of pixels in each frame. A camera includes image sensors that facilitates producing monochrome or color images and videos. Color information may be important in interpreting data for some situations (e.g., interpreting images of traffic lights). Color information may not be available from other sensors such as LiDAR or radar sensors. Camera(s) 232 can include one or more of narrow-focus cameras, wider-focus cameras, side-facing cameras, infrared cameras, fisheye cameras, or the like. The image and/or video data generated by camera(s) 232 can also be provided to vehicle perception and planning system 220 via communication path 233 for further processing and controlling the vehicle operations. Communication path 233 can be any wired or wireless communication links that can transfer data. Camera(s) 232 can be mount on, or integrated to, a vehicle at any locations (e.g., rear-view mirrors, pillars, front grille, and/or back bumpers, etc.).

Other vehicle onboard sensos(s) 230 can also include radar sensor(s) 234. Radar sensor(s) 234 use radio waves to determine the range, angle, and velocity of objects. Radar sensor(s) 234 produce electromagnetic waves in the radio or microwave spectrum. The electromagnetic waves reflect off an object and some of the reflected waves return to the radar sensor, thereby providing information about the object's position and velocity. Radar sensor(s) 234 can include one or more of short-range radar(s), medium-range radar(s), and long-range radar(s). A short-range radar measures objects located at about 0.1-30 meters from the radar. A short-range radar is useful in detecting objects located nearby the vehicle, such as other vehicles, buildings, walls, pedestrians, bicyclists, etc. A short-range radar can be used to detect a blind spot, assist in lane changing, provide rear-end collision warning, assist in parking, provide emergency braking, or the like. A medium-range radar measures objects located at about 30-80 meters from the radar. A long-range radar measures objects located at about 80-200 meters. Medium- and/or long-range radars can be useful in, for example, traffic following, adaptive cruise control, and/or highway automatic braking. Sensor data generated by radar sensor(s) 234 can also be provided to vehicle perception and planning system 220 via communication path 233 for further processing and controlling the vehicle operations. Radar sensor(s) 234 can be mount on, or integrated to, a vehicle at any locations (e.g., rear-view mirrors, pillars, front grille, and/or back bumpers, etc.).

Other vehicle onboard sensor(s) 230 can also include ultrasonic sensor(s) 236. Ultrasonic sensor(s) 236 use acoustic waves or pulses to measure object located external to a vehicle. The acoustic waves generated by ultrasonic sensor(s) 236 are transmitted to the surrounding environment. At least some of the transmitted waves are reflected off an object and return to the ultrasonic sensor(s) 236. Based on the return signals, a distance of the object can be calculated. Ultrasonic sensor(s) 236 can be useful in, for example, checking blind spots, identifying parking spaces, providing lane changing assistance into traffic, or the like. Sensor data generated by ultrasonic sensor(s) 236 can also be provided to vehicle perception and planning system 220 via communication path 233 for further processing and controlling the vehicle operations. Ultrasonic sensor(s) 236 can be mount on, or integrated to, a vehicle at any locations (e.g., rear-view mirrors, pillars, front grille, and/or back bumpers, etc.).

In some embodiments, one or more other sensor(s) 238 may be attached in a vehicle and may also generate sensor data. Other sensor(s) 238 may include, for example, global positioning systems (GPS), inertial measurement units (IMU), or the like. Sensor data generated by other sensor(s) 238 can also be provided to vehicle perception and planning system 220 via communication path 233 for further processing and controlling the vehicle operations. It is understood that communication path 233 may include one or more communication links to transfer data between the various sensor(s) 230 and vehicle perception and planning system 220.

In some embodiments, as shown in FIG. 2, sensor data from other vehicle onboard sensor(s) 230 can be provided to vehicle onboard LiDAR system(s) 210 via communication path 231. LiDAR system(s) 210 may process the sensor data from other vehicle onboard sensor(s) 230. For example, sensor data from camera(s) 232, radar sensor(s) 234, ultrasonic sensor(s) 236, and/or other sensor(s) 238 may be correlated or fused with sensor data LiDAR system(s) 210, thereby at least partially offloading the sensor fusion process performed by vehicle perception and planning system 220. It is understood that other configurations may also be implemented for transmitting and processing sensor data from the various sensors (e.g., data can be transmitted to a cloud or edge computing service provider for processing and then the processing results can be transmitted back to the vehicle perception and planning system 220 and/or LiDAR system 210).

With reference still to FIG. 2, in some embodiments, sensors onboard other vehicle(s) 250 are used to provide additional sensor data separately or together with LiDAR system(s) 210. For example, two or more nearby vehicles may have their own respective LiDAR sensor(s), camera(s), radar sensor(s), ultrasonic sensor(s), etc. Nearby vehicles can communicate and share sensor data with one another. Communications between vehicles are also referred to as V2V (vehicle to vehicle) communications. For example, as shown in FIG. 2, sensor data generated by other vehicle(s) 250 can be communicated to vehicle perception and planning system 220 and/or vehicle onboard LiDAR system(s) 210, via communication path 253 and/or communication path 251, respectively. Communication paths 253 and 251 can be any wired or wireless communication links that can transfer data.

Sharing sensor data facilitates a better perception of the environment external to the vehicles. For instance, a first vehicle may not sense a pedestrian that is behind a second vehicle but is approaching the first vehicle. The second vehicle may share the sensor data related to this pedestrian with the first vehicle such that the first vehicle can have additional reaction time to avoid collision with the pedestrian. In some embodiments, similar to data generated by sensor(s) 230, data generated by sensors onboard other vehicle(s) 250 may be correlated or fused with sensor data generated by LiDAR system(s) 210 (or with other LiDAR systems located in other vehicles), thereby at least partially offloading the sensor fusion process performed by vehicle perception and planning system 220.

In some embodiments, intelligent infrastructure system(s) 240 are used to provide sensor data separately or together with LiDAR system(s) 210. Certain infrastructures may be configured to communicate with a vehicle to convey information and vice versa. Communications between a vehicle and infrastructures are generally referred to as V2I (vehicle to infrastructure) communications. For example, intelligent infrastructure system(s) 240 may include an intelligent traffic light that can convey its status to an approaching vehicle in a message such as “changing to yellow in 5 seconds.” Intelligent infrastructure system(s) 240 may also include its own LiDAR system mounted near an intersection such that it can convey traffic monitoring information to a vehicle. For example, a left-turning vehicle at an intersection may not have sufficient sensing capabilities because some of its own sensors may be blocked by traffic in the opposite direction. In such a situation, sensors of intelligent infrastructure system(s) 240 can provide useful data to the left-turning vehicle. Such data may include, for example, traffic conditions, information of objects in the direction the vehicle is turning to, traffic light status and predictions, or the like. These sensor data generated by intelligent infrastructure system(s) 240 can be provided to vehicle perception and planning system 220 and/or vehicle onboard LiDAR system(s) 210, via communication paths 243 and/or 241, respectively. Communication paths 243 and/or 241 can include any wired or wireless communication links that can transfer data. For example, sensor data from intelligent infrastructure system(s) 240 may be transmitted to LiDAR system(s) 210 and correlated or fused with sensor data generated by LiDAR system(s) 210, thereby at least partially offloading the sensor fusion process performed by vehicle perception and planning system 220. V2V and V2I communications described above are examples of vehicle-to-X (V2X) communications, where the “X” represents any other devices, systems, sensors, infrastructure, or the like that can share data with a vehicle.

With reference still to FIG. 2, via various communication paths, vehicle perception and planning system 220 receives sensor data from one or more of LiDAR system(s) 210, other vehicle onboard sensor(s) 230, other vehicle(s) 250, and/or intelligent infrastructure system(s) 240. In some embodiments, different types of sensor data are correlated and/or integrated by a sensor fusion sub-system 222. For example, sensor fusion sub-system 222 can generate a 360-degree model using multiple images or videos captured by multiple cameras disposed at different positions of the vehicle. Sensor fusion sub-system 222 obtains sensor data from different types of sensors and uses the combined data to perceive the environment more accurately. For example, a vehicle onboard camera 232 may not capture a clear image because it is facing the sun or a light source (e.g., another vehicle's headlight during nighttime) directly. A LiDAR system 210 may not be affected as much and therefore sensor fusion sub-system 222 can combine sensor data provided by both camera 232 and LiDAR system 210, and use the sensor data provided by LiDAR system 210 to compensate the unclear image captured by camera 232. As another example, in a rainy or foggy weather, a radar sensor 234 may work better than a camera 232 or a LiDAR system 210. Accordingly, sensor fusion sub-system 222 may use sensor data provided by the radar sensor 234 to compensate the sensor data provided by camera 232 or LiDAR system 210.

In other examples, sensor data generated by other vehicle onboard sensor(s) 230 may have a lower resolution (e.g., radar sensor data) and thus may need to be correlated and confirmed by LiDAR system(s) 210, which usually has a higher resolution. For example, a sewage cover (also referred to as a manhole cover) may be detected by radar sensor 234 as an object towards which a vehicle is approaching. Due to the low-resolution nature of radar sensor 234, vehicle perception and planning system 220 may not be able to determine whether the object is an obstacle that the vehicle needs to avoid. High-resolution sensor data generated by LiDAR system(s) 210 thus can be used to correlated and confirm that the object is a sewage cover and causes no harm to the vehicle.

Vehicle perception and planning system 220 further comprises an object classifier 223. Using raw sensor data and/or correlated/fused data provided by sensor fusion sub-system 222, object classifier 223 can use any computer vision techniques to detect and classify the objects and estimate the positions of the objects. In some embodiments, object classifier 223 can use machine-learning based techniques to detect and classify objects. Examples of the machine-learning based techniques include utilizing algorithms such as region-based convolutional neural networks (R-CNN), Fast R-CNN, Faster R-CNN, histogram of oriented gradients (HOG), region-based fully convolutional network (R-FCN), single shot detector (SSD), spatial pyramid pooling (SPP-net), and/or You Only Look Once (Yolo).

Vehicle perception and planning system 220 further comprises a road detection sub-system 224. Road detection sub-system 224 localizes the road and identifies objects and/or markings on the road. For example, based on raw or fused sensor data provided by radar sensor(s) 234, camera(s) 232, and/or LiDAR system(s) 210, road detection sub-system 224 can build a 3D model of the road based on machine-learning techniques (e.g., pattern recognition algorithms for identifying lanes). Using the 3D model of the road, road detection sub-system 224 can identify objects (e.g., obstacles or debris on the road) and/or markings on the road (e.g., lane lines, turning marks, crosswalk marks, or the like).

Vehicle perception and planning system 220 further comprises a localization and vehicle posture sub-system 225. Based on raw or fused sensor data, localization and vehicle posture sub-system 225 can determine position of the vehicle and the vehicle's posture. For example, using sensor data from LiDAR system(s) 210, camera(s) 232, and/or GPS data, localization and vehicle posture sub-system 225 can determine an accurate position of the vehicle on the road and the vehicle's six degrees of freedom (e.g., whether the vehicle is moving forward or backward, up or down, and left or right). In some embodiments, high-definition (HD) maps are used for vehicle localization. HD maps can provide highly detailed, three-dimensional, computerized maps that pinpoint a vehicle's location. For instance, using the HD maps, localization and vehicle posture sub-system 225 can determine precisely the vehicle's current position (e.g., which lane of the road the vehicle is currently in, how close it is to a curb or a sidewalk) and predict vehicle's future positions.

Vehicle perception and planning system 220 further comprises obstacle predictor 226. Objects identified by object classifier 223 can be stationary (e.g., a light pole, a road sign) or dynamic (e.g., a moving pedestrian, bicycle, another car). For moving objects, predicting their moving path or future positions can be important to avoid collision. Obstacle predictor 226 can predict an obstacle trajectory and/or warn the driver or the vehicle planning sub-system 228 about a potential collision. For example, if there is a high likelihood that the obstacle's trajectory intersects with the vehicle's current moving path, obstacle predictor 226 can generate such a warning. Obstacle predictor 226 can use a variety of techniques for making such a prediction. Such techniques include, for example, constant velocity or acceleration models, constant turn rate and velocity/acceleration models, Kalman Filter and Extended Kalman Filter based models, recurrent neural network (RNN) based models, long short-term memory (LSTM) neural network based models, encoder-decoder RNN models, or the like.

With reference still to FIG. 2, in some embodiments, vehicle perception and planning system 220 further comprises vehicle planning sub-system 228. Vehicle planning sub-system 228 can include one or more planners such as a route planner, a driving behaviors planner, and a motion planner. The route planner can plan the route of a vehicle based on the vehicle's current location data, target location data, traffic information, etc. The driving behavior planner adjusts the timing and planned movement based on how other objects might move, using the obstacle prediction results provided by obstacle predictor 226. The motion planner determines the specific operations the vehicle needs to follow. The planning results are then communicated to vehicle control system 280 via vehicle interface 270. The communication can be performed through communication paths 223 and 271, which include any wired or wireless communication links that can transfer data.

Vehicle control system 280 controls the vehicle's steering mechanism, throttle, brake, etc., to operate the vehicle according to the planned route and movement. In some examples, vehicle perception and planning system 220 may further comprise a user interface 260, which provides a user (e.g., a driver) access to vehicle control system 280 to, for example, override or take over control of the vehicle when necessary. User interface 260 may also be separate from vehicle perception and planning system 220. User interface 260 can communicate with vehicle perception and planning system 220, for example, to obtain and display raw or fused sensor data, identified objects, vehicle's location/posture, etc. These displayed data can help a user to better operate the vehicle. User interface 260 can communicate with vehicle perception and planning system 220 and/or vehicle control system 280 via communication paths 221 and 261 respectively, which include any wired or wireless communication links that can transfer data. It is understood that the various systems, sensors, communication links, and interfaces in FIG. 2 can be configured in any desired manner and not limited to the configuration shown in FIG. 2.

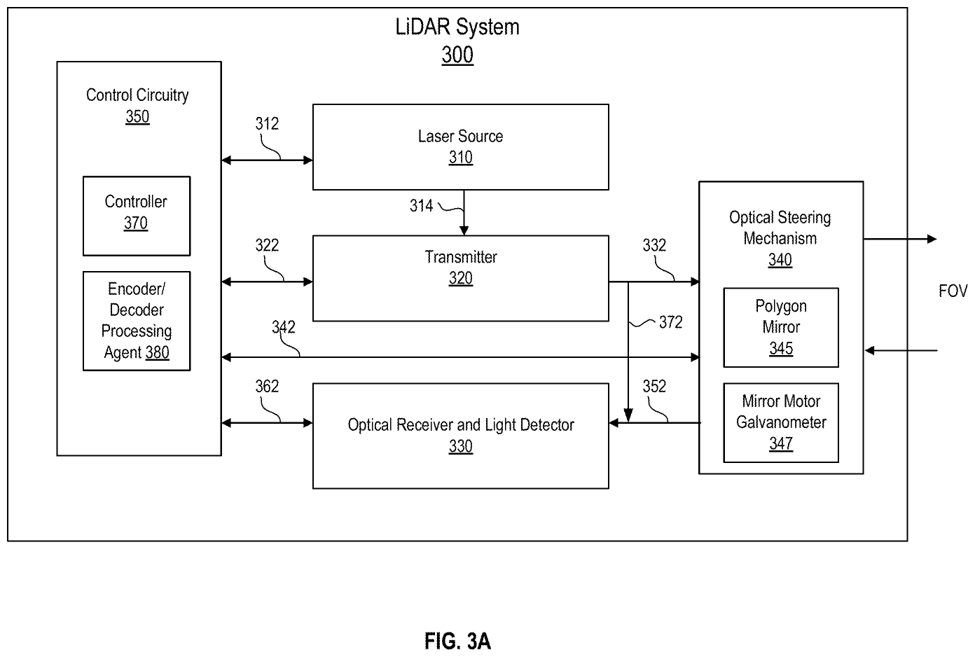

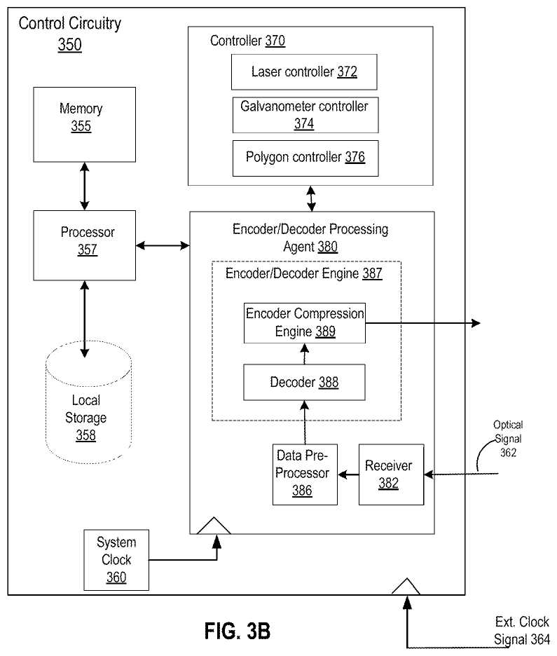

FIG. 3A is a block diagram illustrating an example LiDAR system 300. LiDAR system 300 can be used to implement LiDAR systems 110, 120A-120I, and/or 210 shown in FIGS. 1 and 2. In one embodiment, LiDAR system 300 comprises a light source 310, a transmitter 320, an optical receiver and light detector 330, an optical steering mechanism 340, and control circuitry 350. The components shown in FIG. 3A are coupled together using communications paths 312, 314, 322, 332, 342, 352, and 362. These communications paths represent communication (bidirectional or unidirectional) among the various LiDAR system components but need not be physical components themselves. While the communications paths can be implemented by one or more electrical wires, busses, or optical fibers, the communication paths can also be wireless channels or open-air optical paths so that no physical communication medium is present. For example, in one example LiDAR system, communication path 314 includes one or more optical fibers; communication path 352 represents an optical path; and communication paths 312, 322, 342, and 362 are all electrical wires that carry electrical signals. The communication paths can also include more than one of the above types of communication mediums (e.g., they can include an optical fiber and an optical path, or one or more optical fibers and one or more electrical wires).

In some embodiments, LiDAR system 300 can be a coherent LiDAR system. One example is a frequency-modulated continuous-wave (FMCW) LiDAR. Coherent LiDARs detect objects by mixing return light from the objects with light from the coherent laser transmitter. Thus, as shown in FIG. 3A, if LiDAR system 300 is a coherent LiDAR, it may include a route 372 providing a portion of transmission light from transmitter 320 to optical receiver and light detector 330. The transmission light provided by transmitter 320 may be modulated light and can be split into two portions. One portion is transmitted to the FOV, while the second portion is sent to the optical receiver and light detector of the LiDAR system. The second portion is also referred to as the light that is kept local (LO) to the LiDAR system. The transmission light is scattered or reflected by various objects in the FOV and at least a portion of it forms return light. The return light is subsequently detected and interferometrically recombined with the second portion of the transmission light that was kept local. Coherent LiDAR provides a means of optically sensing an object's range as well as its relative velocity along the line-of-sight (LOS).

LiDAR system 300 can also include other components not depicted in FIG. 3A, such as power buses, power supplies, LED indicators, switches, etc. Additionally, other communication connections among components may be present, such as a direct connection between light source 310 and optical receiver and light detector 330 to provide a reference signal so that the time from when a light pulse is transmitted until a return light pulse is detected can be accurately measured.

Light source 310 outputs laser light for illuminating objects in a field of view (FOV). The laser light can be infrared light having a wavelength in the range of 700 nm to 1 mm. Light source 310 can be, for example, a semiconductor-based laser (e.g., a diode laser) and/or a fiber-based laser. A semiconductor-based laser can be, for example, an edge emitting laser (EEL), a vertical cavity surface emitting laser (VCSEL), an external-cavity diode laser, a vertical-external-cavity surface-emitting laser, a distributed feedback (DFB) laser, a distributed Bragg reflector (DBR) laser, an interband cascade laser, a quantum cascade laser, a quantum well laser, a double heterostructure laser, or the like. A fiber-based laser is a laser in which the active gain medium is an optical fiber doped with rare-earth elements such as erbium, ytterbium, neodymium, dysprosium, praseodymium, thulium and/or holmium. In some embodiments, a fiber laser is based on double-clad fibers, in which the gain medium forms the core of the fiber surrounded by two layers of cladding. The double-clad fiber allows the core to be pumped with a high-power beam, thereby enabling the laser source to be a high power fiber laser source.

In some embodiments, light source 310 comprises a master oscillator (also referred to as a seed laser) and power amplifier (MOPA). The power amplifier amplifies the output power of the seed laser. The power amplifier can be a fiber amplifier, a bulk amplifier, or a semiconductor optical amplifier. The seed laser can be a diode laser (e.g., a Fabry-Perot cavity laser, a distributed feedback laser), a solid-state bulk laser, or a tunable external-cavity diode laser. In some embodiments, light source 310 can be an optically pumped microchip laser. Microchip lasers are alignment-free monolithic solid-state lasers where the laser crystal is directly contacted with the end mirrors of the laser resonator. A microchip laser is typically pumped with a laser diode (directly or using a fiber) to obtain the desired output power. A microchip laser can be based on neodymium-doped yttrium aluminum garnet (Y₃Al₅O₁₂) laser crystals (i.e., Nd:YAG), or neodymium-doped vanadate (i.e., ND:YVO₄) laser crystals. In some examples, light source 310 may have multiple amplification stages to achieve a high power gain such that the laser output can have high power, thereby enabling the LiDAR system to have a long scanning range. In some examples, the power amplifier of light source 310 can be controlled such that the power gain can be varied to achieve any desired laser output power.

Referencing to FIG. 3A, typical operating wavelengths of light source 310 comprise, for example, about 850 nm, about 905 nm, about 940 nm, about 1064 nm, and about 1550 nm. For laser safety, the upper limit of maximum usable laser power is set by the U.S. FDA (U.S. Food and Drug Administration) regulations. The optical power limit at 1550 nm wavelength is much higher than those of the other aforementioned wavelengths. Further, at 1550 nm, the optical power loss in a fiber is low. There characteristics of the 1550 nm wavelength make it more beneficial for long-range LiDAR applications. The amount of optical power output from light source 310 can be characterized by its peak power, average power, pulse energy, and/or the pulse energy density. The peak power is the ratio of pulse energy to the width of the pulse (e.g., full width at half maximum or FWHM). Thus, a smaller pulse width can provide a larger peak power for a fixed amount of pulse energy. A pulse width can be in the range of nanosecond or picosecond. The average power is the product of the energy of the pulse and the pulse repetition rate (PRR). As described in more detail below, the PRR represents the frequency of the pulsed laser light. In general, the smaller the time interval between the pulses, the higher the PRR. The PRR typically corresponds to the maximum range that a LiDAR system can measure. Light source 310 can be configured to produce pulses at high PRR to meet the desired number of data points in a point cloud generated by the LiDAR system. Light source 310 can also be configured to produce pulses at medium or low PRR to meet the desired maximum detection distance. Wall plug efficiency (WPE) is another factor to evaluate the total power consumption, which may be a useful indicator in evaluating the laser efficiency. For example, as shown in FIG. 1, multiple LiDAR systems may be attached to a vehicle, which may be an electrical-powered vehicle or a vehicle otherwise having limited fuel or battery power supply. Therefore, high WPE and intelligent ways to use laser power are often among the important considerations when selecting and configuring light source 310 and/or designing laser delivery systems for vehicle-mounted LiDAR applications.

It is understood that the above descriptions provide non-limiting examples of a light source 310. Light source 310 can be configured to include many other types of light sources (e.g., laser diodes, short-cavity fiber lasers, solid-state lasers, and/or tunable external cavity diode lasers) that are configured to generate one or more light signals at various wavelengths. In some examples, light source 310 comprises amplifiers (e.g., pre-amplifiers and/or booster amplifiers), which can be a doped optical fiber amplifier, a solid-state bulk amplifier, and/or a semiconductor optical amplifier. The amplifiers are configured to receive and amplify light signals with desired gains.

With reference to FIG. 3A, LiDAR system 300 further comprises a transmitter 320. Light source 310 provides laser light (e.g., in the form of a laser beam) to transmitter 320. The laser light provided by light source 310 can be amplified laser light with a predetermined or controlled wavelength, pulse repetition rate, and/or power level. Transmitter 320 receives the laser light from light source 310 and transmits the laser light to optical steering mechanism 340 with low divergence. In some embodiments, transmitter 320 can include, for example, optical components (e.g., lens, fibers, mirrors, etc.) for transmitting one or more laser beams to a field-of-view (FOV) directly or via optical steering mechanism 340. While FIG. 3 illustrates transmitter 320 and optical steering mechanism 340 as separate components, they may be combined or integrated as one system in some embodiments. Optical steering mechanism 340 is described in more detail below.

Laser beams provided by light source 310 may diverge as they travel to transmitter 320. Therefore, transmitter 320 often comprises a collimating lens configured to collect the diverging laser beams and produce more parallel optical beams with reduced or minimum divergence. The collimated optical beams can then be further directed through various optics such as mirrors and lens. A collimating lens may be, for example, a single plano-convex lens or a lens group. The collimating lens can be configured to achieve any desired properties such as the beam diameter, divergence, numerical aperture, focal length, or the like. A beam propagation ratio or beam quality factor (also referred to as the M² factor) is used for measurement of laser beam quality. In many LiDAR applications, it is important to have good laser beam quality in the generated transmitting laser beam. The M² factor represents a degree of variation of a beam from an ideal Gaussian beam. Thus, the M² factor reflects how well a collimated laser beam can be focused on a small spot, or how well a divergent laser beam can be collimated. Therefore, light source 310 and/or transmitter 320 can be configured to meet, for example, a scan resolution requirement while maintaining the desired M² factor.

One or more of the light beams provided by transmitter 320 are scanned by optical steering mechanism 340 to a FOV. Optical steering mechanism 340 scans light beams in multiple dimensions (e.g., in both the horizontal and vertical dimension) to facilitate LiDAR system 300 to map the environment by generating a 3D point cloud. A horizontal dimension can be a dimension that is parallel to the horizon or a surface associated with the LiDAR system or a vehicle (e.g., a road surface). A vertical dimension is perpendicular to the horizontal dimension (i.e., the vertical dimension forms a 90-degree angle with the horizontal dimension). Optical steering mechanism 340 will be described in more detail below. The laser light scanned to an FOV may be scattered or reflected by an object in the FOV. At least a portion of the scattered or reflected light forms return light that returns to LiDAR system 300.

FIG. 3A further illustrates an optical receiver and light detector 330 configured to receive the return light. Optical receiver and light detector 330 comprises an optical receiver that is configured to collect the return light from the FOV. The optical receiver can include optics (e.g., lens, fibers, mirrors, etc.) for receiving, redirecting, focusing, amplifying, and/or filtering return light from the FOV. For example, the optical receiver often includes a collection lens (e.g., a single plano-convex lens or a lens group) to collect and/or focus the collected return light onto a light detector.

A light detector detects the return light focused by the optical receiver and generates current and/or voltage signals proportional to the incident intensity of the return light. Based on such current and/or voltage signals, the depth information of the object in the FOV can be derived. One example method for deriving such depth information is based on the direct TOF (time of flight), which is described in more detail below. A light detector may be characterized by its detection sensitivity, quantum efficiency, detector bandwidth, linearity, signal to noise ratio (SNR), overload resistance, interference immunity, etc. Based on the applications, the light detector can be configured or customized to have any desired characteristics. For example, optical receiver and light detector 330 can be configured such that the light detector has a large dynamic range while having a good linearity. The light detector linearity indicates the detector's capability of maintaining linear relationship between input optical signal power and the detector's output. A detector having good linearity can maintain a linear relationship over a large dynamic input optical signal range.

To achieve desired detector characteristics, configurations or customizations can be made to the light detector's structure and/or the detector's material system. Various detector structure can be used for a light detector. For example, a light detector structure can be a PIN based structure, which has a undoped intrinsic semiconductor region (i.e., an “i” region) between a p-type semiconductor and an n-type semiconductor region. Other light detector structures comprise, for example, an APD (avalanche photodiode) based structure, a PMT (photomultiplier tube) based structure, a SiPM (Silicon photomultiplier) based structure, a SPAD (single-photon avalanche diode) based structure, and/or quantum wires. For material systems used in a light detector, Si, InGaAs, and/or Si/Ge based materials can be used. It is understood that many other detector structures and/or material systems can be used in optical receiver and light detector 330.

A light detector (e.g., an APD based detector) may have an internal gain such that the input signal is amplified when generating an output signal. However, noise may also be amplified due to the light detector's internal gain. Common types of noise include signal shot noise, dark current shot noise, thermal noise, and amplifier noise. In some embodiments, optical receiver and light detector 330 may include a pre-amplifier that is a low noise amplifier (LNA). In some embodiments, the pre-amplifier may also include a transimpedance amplifier (TIA), which converts a current signal to a voltage signal. For a linear detector system, input equivalent noise or noise equivalent power (NEP) measures how sensitive the light detector is to weak signals. Therefore, they can be used as indicators of the overall system performance. For example, the NEP of a light detector specifies the power of the weakest signal that can be detected and therefore it in turn specifies the maximum range of a LiDAR system. It is understood that various light detector optimization techniques can be used to meet the requirement of LiDAR system 300. Such optimization techniques may include selecting different detector structures, materials, and/or implementing signal processing techniques (e.g., filtering, noise reduction, amplification, or the like). For example, in addition to, or instead of, using direct detection of return signals (e.g., by using ToF), coherent detection can also be used for a light detector. Coherent detection allows for detecting amplitude and phase information of the received light by interfering the received light with a local oscillator. Coherent detection can improve detection sensitivity and noise immunity.

FIG. 3A further illustrates that LiDAR system 300 comprises optical steering mechanism 340. As described above, optical steering mechanism 340 directs light beams from transmitter 320 to scan an FOV in multiple dimensions. An optical steering mechanism is referred to as a raster mechanism, a scanning mechanism, or simply a light scanner. Scanning light beams in multiple directions (e.g., in both the horizontal and vertical directions) facilitates a LiDAR system to map the environment by generating an image or a 3D point cloud. An optical steering mechanism can be based on mechanical scanning and/or solid-state scanning. Mechanical scanning uses rotating mirrors to steer the laser beam or physically rotate the LiDAR transmitter and receiver (collectively referred to as transceiver) to scan the laser beam. Solid-state scanning directs the laser beam to various positions through the FOV without mechanically moving any macroscopic components such as the transceiver. Solid-state scanning mechanisms include, for example, optical phased arrays based steering and flash LiDAR based steering. In some embodiments, because solid-state scanning mechanisms do not physically move macroscopic components, the steering performed by a solid-state scanning mechanism may be referred to as effective steering. A LiDAR system using solid-state scanning may also be referred to as a non-mechanical scanning or simply non-scanning LiDAR system (a flash LiDAR system is an example non-scanning LiDAR system).

Optical steering mechanism 340 can be used with a transceiver (e.g., transmitter 320 and optical receiver and light detector 330) to scan the FOV for generating an image or a 3D point cloud. As an example, to implement optical steering mechanism 340, a two-dimensional mechanical scanner can be used with a single-point or several single-point transceivers. A single-point transceiver transmits a single light beam or a small number of light beams (e.g., 2-8 beams) to the optical steering mechanism. A two-dimensional mechanical optical steering mechanism comprises, for example, polygon mirror(s), oscillating mirror(s), rotating prism(s), rotating tilt mirror surface(s), single-plane or multi-plane mirror(s), or a combination thereof. In some embodiments, optical steering mechanism 340 may include non-mechanical optical steering mechanism(s) such as solid-state optical steering mechanism(s). For example, optical steering mechanism 340 can be based on tuning wavelength of the laser light combined with refraction effect, and/or based on reconfigurable grating/phase array. In some embodiments, optical steering mechanism 340 can use a single scanning device to achieve two-dimensional scanning or multiple scanning devices combined to realize two-dimensional scanning.

As another example, to implement optical steering mechanism 340, a one-dimensional mechanical scanner can be used with an array or a large number of single-point transceivers. Specifically, the transceiver array can be mounted on a rotating platform to achieve 360-degree horizontal field of view. Alternatively, a static transceiver array can be combined with the one-dimensional mechanical scanner. A one-dimensional mechanical scanner comprises polygon mirror(s), oscillating mirror(s), rotating prism(s), rotating tilt mirror surface(s), or a combination thereof, for obtaining a forward-looking horizontal field of view. Optical steering mechanisms using mechanical scanners can provide robustness and reliability in high volume production for automotive applications.

As another example, to implement optical steering mechanism 340, a two-dimensional transceiver can be used to generate a scan image or a 3D point cloud directly. In some embodiments, a stitching or micro shift method can be used to improve the resolution of the scan image or the field of view being scanned. For example, using a two-dimensional transceiver, signals generated at one direction (e.g., the horizontal direction) and signals generated at the other direction (e.g., the vertical direction) may be integrated, interleaved, and/or matched to generate a higher or full resolution image or 3D point cloud representing the scanned FOV.

Some implementations of optical steering mechanism 340 comprise one or more optical redirection elements (e.g., mirrors or lenses) that steer return light signals (e.g., by rotating, vibrating, or directing) along a receive path to direct the return light signals to optical receiver and light detector 330. The optical redirection elements that direct light signals along the transmitting and receiving paths may be the same components (e.g., shared), separate components (e.g., dedicated), and/or a combination of shared and separate components. This means that in some cases the transmitting and receiving paths are different although they may partially overlap (or in some cases, substantially overlap or completely overlap).

With reference still to FIG. 3A, LiDAR system 300 further comprises control circuitry 350. Control circuitry 350 can be configured and/or programmed to control various parts of the LiDAR system 300 and/or to perform signal processing. In a typical system, control circuitry 350 can be configured and/or programmed to perform one or more control operations including, for example, controlling light source 310 to obtain the desired laser pulse timing, the pulse repetition rate, and power; controlling optical steering mechanism 340 (e.g., controlling the speed, direction, and/or other parameters) to scan the FOV and maintain pixel registration and/or alignment; controlling optical receiver and light detector 330 (e.g., controlling the sensitivity, noise reduction, filtering, and/or other parameters) such that it is an optimal state; and monitoring overall system health/status for functional safety (e.g., monitoring the laser output power and/or the steering mechanism operating status for safety).

Control circuitry 350 can also be configured and/or programmed to perform signal processing to the raw data generated by optical receiver and light detector 330 to derive distance and reflectance information, and perform data configuration such as encoding and compression. Control circuitry 350 can communicate configured output data to vehicle perception and planning system 220 (shown in FIG. 2) and/or other internal or external systems. For example, control circuitry 350 determines the time it takes from transmitting a light pulse until a corresponding return light pulse is received; determines when a return light pulse is not received for a transmitted light pulse; determines the direction (e.g., horizontal and/or vertical information) for a transmitted/return light pulse; determines the estimated range in a particular direction; derives the reflectivity of an object in the FOV, and/or determines any other type of data relevant to LiDAR system 300.

LiDAR system 300 can be disposed in a vehicle, which may operate in many different environments including hot or cold weather, rough road conditions that may cause intense vibration, high or low humidities, dusty areas, etc. Therefore, in some embodiments, optical and/or electronic components of LiDAR system 300 (e.g., optics in transmitter 320, optical receiver and light detector 330, and optical steering mechanism 340) are disposed and/or configured in such a manner to maintain long term mechanical and optical stability. For example, components in LiDAR system 300 may be secured and sealed such that they can operate under all conditions a vehicle may encounter. As an example, an anti-moisture coating and/or hermetic sealing may be applied to optical components of transmitter 320, optical receiver and light detector 330, and optical steering mechanism 340 (and other components that are susceptible to moisture). As another example, housing(s), enclosure(s), fairing(s), and/or window can be used in LiDAR system 300 for providing desired characteristics such as hardness, ingress protection (IP) rating, self-cleaning capability, resistance to chemical and resistance to impact, or the like. In addition, efficient and economical methodologies for assembling LiDAR system 300 may be used to meet the LiDAR operating requirements while keeping the cost low.

It is understood by a person of ordinary skill in the art that FIG. 3A and the above descriptions are for illustrative purposes only, and a LiDAR system can include other functional units, blocks, or segments, and can include variations or combinations of these above functional units, blocks, or segments. For example, LiDAR system 300 can also include other components not depicted in FIG. 3A, such as power buses, power supplies, LED indicators, switches, etc. Additionally, other connections among components may be present, such as a direct connection between light source 310 and optical receiver and light detector 330 so that light detector 330 can accurately measure the time from when light source 310 transmits a light pulse until light detector 330 detects a return light pulse.

As described above, LiDAR system 300 includes a control circuitry 350. With reference to FIG. 3A, in some examples, control circuitry 350 comprises a controller 370 and an encoder/decoder processing agent 380. The optical steering mechanism 340 comprises, for example, a rotatable polygon mirror 345 and mirror motor galvanometer 347. In one example, the light source 310 couples to supply one or more of light pulses to optical steering mechanism 340 (directly or via transmitter 320), wherein the optical steering mechanism 340 directs the one or more light pulses in accordance with a field of view (FOV). Rotatable polygon mirror 345 implements horizontal motion scanning of the FOV using the one or more light pulses; while mirror motor galvanometer 347 implements vertical motion scanning of the FOV. Optical receiver and light detector 330 couples to receive a return light pulse of an object in the respective path of the one or more light pulses within the FOV to generate detection data.

In some embodiments, encoder/decoder processing agent 380 couples to receive detection data from optical receiver and light detector 330 via communication path 362. Encoder/decoder processing agent 380 transforms the detection data into raw data. The detection data may include, for example analog or digital data (provided by an analog-to-digital converter) representing the return light pulses. Agent 380 further configures output data from trigger data, encoder data, time synchronization data, and the raw data. Each of these types of data are described in greater details below. Encoder/decoder processing agent 380 configures the output data in a compressed format that includes a data set for one baseline channel and differential channel data for one or more channels based upon the baseline channel. For instance, LiDAR system 300 may have 4 transceiver channels, each of which are used to obtain detection data, from which raw data are generated. The first transceiver channel may be used as a baseline channel, and the data of the additional 3 channels are referenced to the baseline channel, thereby implementing the compression of data for the 3 additional channels. This compressed format of the output data conserves storage space and processing time. Furthermore, the compressed data format can reduce the bandwidth requirements for providing the output data to downstream processing (e.g., perception or sensor fusion based on the LiDAR system's point cloud output data).

In some examples, light source 310 couples to receive the trigger data from control circuitry 350 to control emission timing of the one or more of light pulses provided by light source 310. The trigger data may be sent from a controller 370 to light source 310. This trigger data can be used to calculate object distances and thus are often included as a part of the point cloud output data of the LiDAR system for enabling downstream processing. The trigger data can be obtained from the controller 370 and included in the compressed output data provided by the LiDAR system for downstream processing. Optical steering mechanism 340 may include position encoders for galvanometer 347 and polygon mirror 345. These position encoders provide position encoder data such as angular positions of mirror motor galvanometer 347 and rotatable polygon mirror 345, timestamps, region of interests (ROI), etc. In some examples, the encoder data are provided by the optical steering mechanism 340 to encoder/decoder processing agent 380 of control circuitry 350. Controller 370 couples to receive the encoder data from the encoder/decoder processing agent 380. Based on the encoder data, controller 370 is coupled to the optical steering mechanism 340 and the light source 310 to coordinate movement speed of the integrated mirror motor galvanometer 347 and the rotatable polygon mirror 345 with the plurality of light pulses supplied by the laser source 310.

FIG. 3B is a block diagram illustrating an example of control circuitry 350 of LiDAR system 300 of FIG. 3A, in accordance with some embodiments. In some examples, control circuitry 350 includes a controller 370 and an encoder/decoder processing agent 380. The controller 370 includes a laser controller 372, a galvanometer controller 374, and a polygon controller 376. The encoder/decoder processing agent 380 includes a receiver 382, a data pre-processor 386, and an encoder/decoder engine 387. The encoder/decoder engine 387 includes a decoder 388 and an encoder compression engine 389. System clock 360 couples to the encoder/decoder processing agent 380. As described below, system clock 360 can be used to generate internal timestamps such as laser trigger timestamps. System clock 360 may not be referenced to an external clock signal, which may represent a time in the physical environment (e.g., a real world clock). In some examples, an external clock signal 364 representing the real world clock couples to control circuitry 350.

Receiver 382 of encoder/decoder processing agent 380 couples to receive detection data representing optical signals 362. The optical signals 362 are detected return light pulses formed by objects in the FOV. Data pre-processor 386 performs filtering in preparation to transform the detection data into raw data. For instance, unwanted signals such as noise, scattered light signals from internal of the LiDAR system are filtered out. The filtering can be performed in analog and/or digital domain. Detection data include pulse data such as pulse intensities and pulse time stamps. In some embodiments, data pre-processor unit 386 also performs some of the initial encoding of analog data from receiver 382 and the time stamps into raw encoded data. Decoder 388 couples to receive the raw encoded data and decode the same. For example, decoder 388 may perform some associated calculations (e.g., from time stamps to ToF and angles). Encoder compression engine 389 couples to receive the decoded data to transform the data into raw data. In some examples, encoder compression engine 389 also receives trigger data, encoder data, and time synchronization data. By using these data and raw data, encoder compression engine 389 configures output data. In a multiple transceiver channels setting, encoder compression engine 389 configures the output data in a compressed format that includes a data set for one baseline channel and differential channel data for one or more channels based upon the baseline channel. This compressed format conserves storage space and processing time. The output data in compressed format can thus be efficiently stored or communicated to external systems for down streaming processing.

With continued reference to FIGS. 3A and 3B, in some examples, light source 310 couples to controller 370 to control emission timing of the one or more of light pulses. Trigger data is associated with laser triggering of the light source 310. Optical steering mechanism 340 (shown in FIG. 3A) couples to provide the encoder data generated by position encoders of the mirror motor galvanometer 347 and rotatable polygon mirror 345. Laser controller 372, galvanometer controller 374, and a polygon controller 376 of controller 370 can receive data from the encoder/decoder processing agent 380. For instance, galvanometer controller 374 couples to receive encoder data from the encoder/decoder processing agent 380 to generate a galvanometer control signal based on the galvanometer position encoder data for controlling the movement the mirror motor galvanometer 347. Polygon controller 376 couples to receive encoder data from the encoder/decoder processing agent 380 to generate a polygon control signal based on the polygon mirror position encoder data for controlling the rotatable polygon mirror 345. Light pulses are triggered or controlled by the laser controller 372. This control is done based on a set timing pattern of pulse triggers. This timing pattern may be modified if needed to increase or decrease LiDAR resolution in different regions of FoV scanning.

Trigger data represents the time value of when receiver 382 detects a part of the light pulse transmitted through a feedback channel. That is, a part of the light pulse is reflected back internally (inside the LiDAR system's optical pathway) toward the receiver 382. When the receiver 382 (through the feedback channel) detects that part of the light pulse, the trigger data is generated with a timestamp of when receiver 382 detects that the light pulse has been transmitted. Since the timing pattern of the light pulses may not be constant, there may also be delays in the LiDAR system. As a result, the actual time of when the light pulse is transmitted out of the LiDAR system is detected, as opposed to when the controller sent the trigger signal to the laser. This physical feedback detection of the light pulse, as the trigger data, represents Time 0 for the Time of flight (ToF) calculation.

In some embodiments, processor 357 is a field programmable gate array (FPGA) or an application specific integrated circuit (ASIC) type processor. Encoder/decoder processing agent 380 can include one or more processors and/or be combined with processor 357. Processor 357 in cooperation with the encoder/decoder processing agent 380 sends output data having four data types to an internal or external system having software models or algorithms for subsequent processing (e.g., perception, sensor fusion, etc.). The output data having these four data types can be sent in a single data stream in the order in which events corresponding to the data happen. Each data type uses 3 or 4 bits at the beginning to identify which data type is sent. The downstream systems can thus decode the received point cloud data based on the data type accordingly. The data “type” indicates which one or more of the four data sets are encoded in the data stream. The four data sets include, for example, trigger data, encoder data, raw data, and time synchronization data.

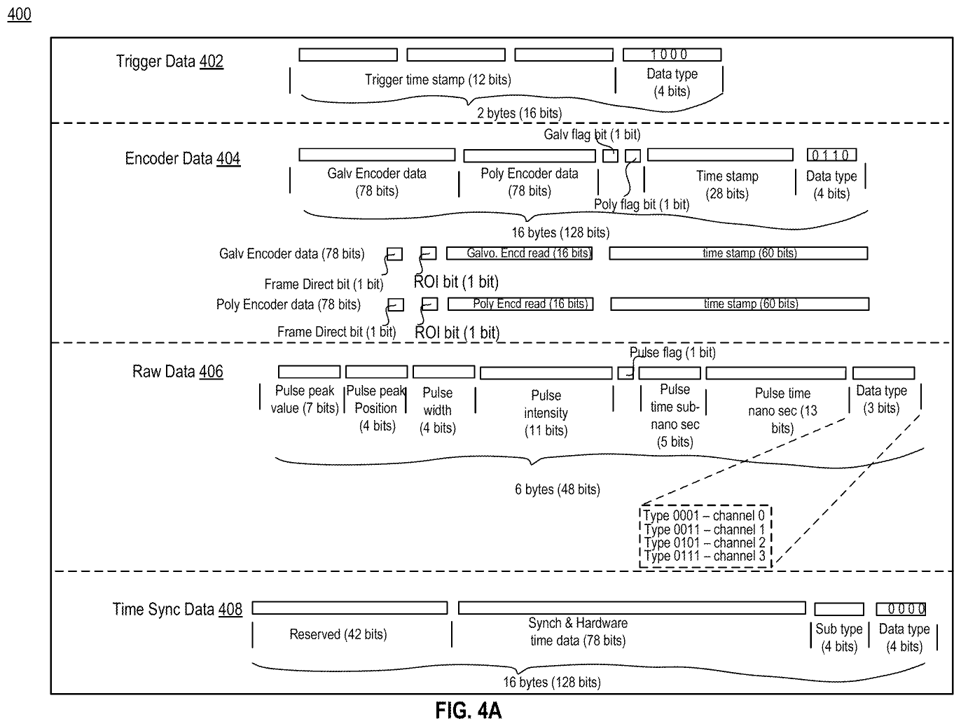

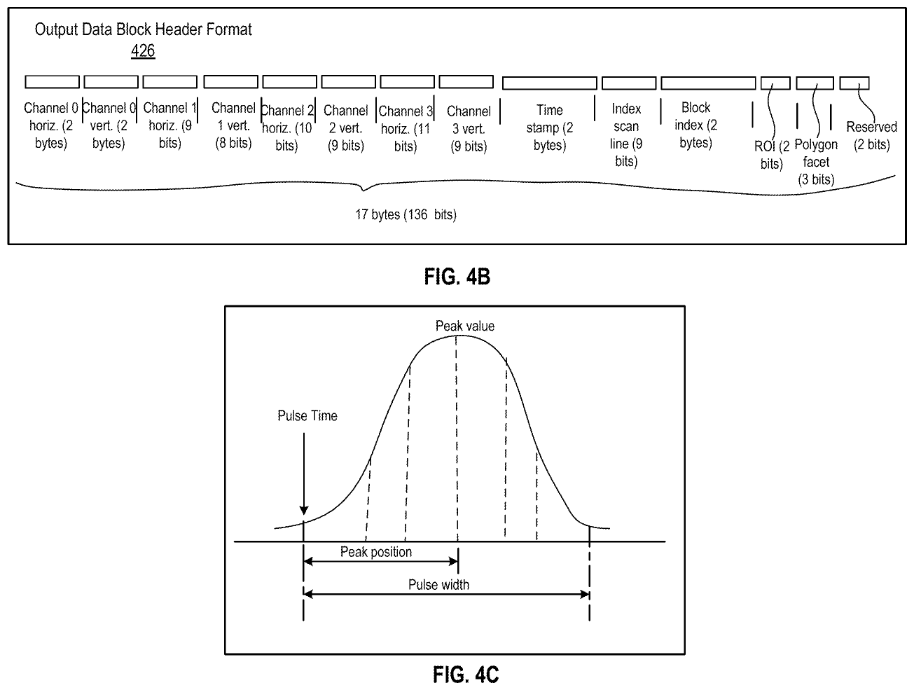

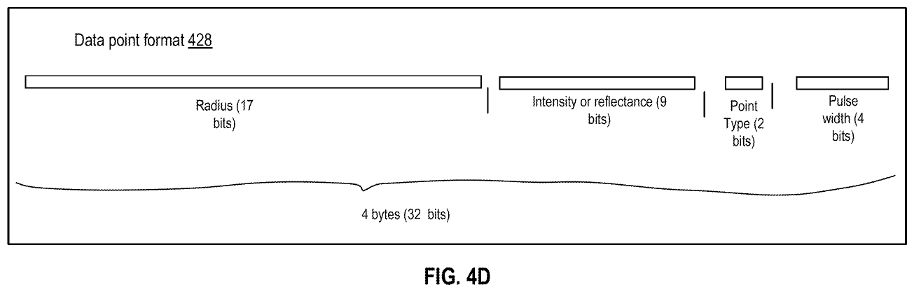

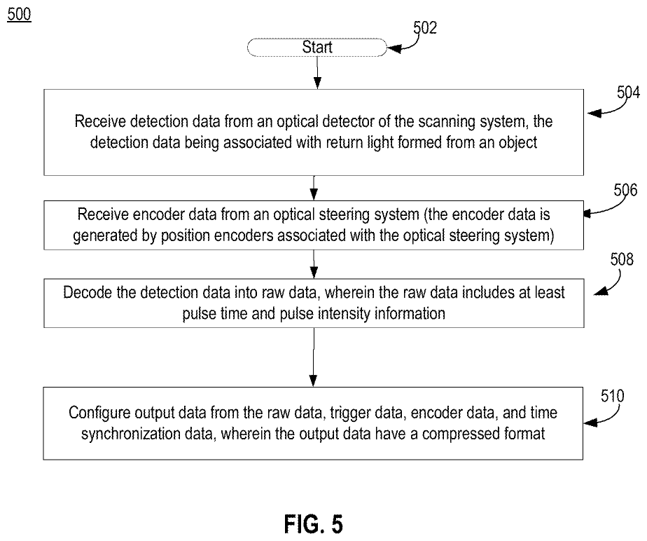

FIG. 4A illustrates an example format of trigger data 402, encoder data 404, raw data 406, and time synchronization data 408, in accordance with some embodiments. The trigger data 402 includes between 2-3 bytes (i.e., 16-24 bits), wherein four (4) bits are used for a data type identification segment and twelve to twenty (12-20) bits are used for a trigger time stamp segment. The trigger time stamp is based on a system clock 360 shown in FIG. 4A. System clock 360 starts when the LiDAR system is connected to a power source, like a vehicle battery. This system clock is not referenced to an external clock signal. In some examples, the trigger data may include a data type indicated by the decimal number 8 represented in binary bits (i.e., “1000”). It is understood that the data type can be represented by any binary number or decimal number, so long as the number distinguishes the data type. The trigger data is generated by data pre-processor 386, as raw data. The trigger data is generated based on when receiver 382 detects a part of the light pulse reflected back toward receiver 382. This trigger data is internal feedback detection data.

With continued reference to FIG. 4A, the encoder data 404 encode the polygon mirror position encoder data and galvanometer position encoder data. In some examples, the encoder data 404 includes 16 bytes (i.e., 128 bits), where four (4) bits are used in a data type identification segment. In some examples, the encoder data may include a data type indicated by the decimal number 6 represented in binary bits (i.e., “0110”). Encoder data 404 also include 28 bits in a time stamp segment representing a time stamp; 1 bit as a polygon flag bit indicating if the data is polygon encoder data; and 1 bit as a galvanometer flag bit indicating if the data is galvanometer encoder data. Encoder data 404 also include a galvanometer encoder data segment and a polygon encoder segment. When the data is galvanometer encoder data, the data in the galvanometer encoder data segment is formatted such that 1 bit indicates a frame direction; 1 bit indicates a Region of Interest (ROI); 16 bits represent a galvanometer encoder reading segment, and 60 bits represent time stamp segment. When the data is polygon encoder data, the data in the polygon encoder data segment is formatted such that 1 bit indicates a frame direction; 1 bit indicates a Region of Interest (ROI); 16 bits represent a polygon encoder reading segment; and 60 bits represent time stamp segment. For both polygon mirror and galvanometer encoder data, 60 bits are used for absolute timestamp.

Referring back to FIG. 3A, LiDAR system 300 includes optical steering mechanism 340 that comprises polygon mirror 345 and galvanometer 347. Each of the polygon mirror 345 and the galvanometer 347 includes a position encoder that provides position encoder data. The position encoder data represent angular positions of polygon mirror 345 and galvanometer 347 at any time points. The position encoder data are included in encoder data 404 shown in FIG. 4A. In some embodiments, not all 128 bits of encoder data 404 are used and thus there may be some unused data bits. In some embodiments, the 28-bit timestamp and the 60-bit absolute timestamp are both timestamps based on system clock 360 shown in FIG. 3B. System clock 360 can be a clock for encoder/decoder processing agent 380 and/or processor 357. Both timestamps represent the same value of time of when the encoder data is encoded. Both timestamps are redundant to each other, where the 60-bit timestamp has the larger range. This timestamp is referred to as the “absolute timestamp” because it has all of the bits of system clock 360. The 28-bit timestamp represents the lowest 28 bits. Thus, the redundant bits may be eliminated.

With reference back to FIG. 4A, raw data 406 are used to encode the pulse data, also referred to as the detection data. The pulse data or detection data are generated based on return light pulses received by the LiDAR system. In some examples, the raw data includes 6 bytes (i.e., 48 bits), where three (3) bits of a data type identification segment represent a data type. In some examples, the raw data may include a data type represented by a prime number such as 1, 2, 5, and/or 7 in binary bits (i.e., “0001”). For example, data type 1 represents data from channel 0; data type 3 represents data from channel 1; data type 5 represents data from channel 2; and data type 7 represents data from channel 3. Out of the 6 bytes (i.e., 48 bits), the raw data 406 may also include, for example, 13 bits of a first pulse time segment used for representing a pulse time in nanoseconds; 5 bits of a second pulse segment used for representing a pulse time in sub-nanoseconds; 1 bit as a pulse flag bit used for representing a reference pulse flag; 11 bits of a pulse intensity segment used for representing a pulse intensity (among them 7 bits are used for intensity base, 4 bits are used for intensity exponent); 4 bits of a pulse width segment used for representing a pulse width; 4 bits of a pulse peak position segment used for representing a pulse peak position; and 7 bits of a pulse peak value segment used for representing a pulse peak value. The 18-bits of the first and second pulse time segments represent the timestamp of when a pulse detection by the receiver occurred. It is based on the system clock 360 shown in FIG. 3B.

In some examples, the reference pulse flag in raw data 406 indicates that a detected pulse is a reference pulse, wherein the pulse is sent directly from a transmitter 320 to the receiver 330 (shown in FIG. 3A) using a designated reference signal channel. When the reference pulse is detected, system 300 interprets it as a baseline time (Time-Zero) indicating when the transmitted pulse actually leaves the transmitter 320. A small delay exists between the trigger timestamp and the detection of the reference pulse.

FIG. 4C is a diagram illustrating an example return light pulse and its associated peak position and pulse width, in accordance with some embodiments. An object in a FOV reflects or scatters transmission light pulses to form the return light pulse, which is received by a LiDAR system (e.g., system 300 shown in FIGS. 3A-3B). The return light pulses are represented by raw data. The diagram shown in FIG. 4C may represent an analog waveform or discreate samples of an analog waveform of a pulse signal. As noted supra, the raw data comprise 4 bits representing a pulse width; 4 bits representing a pulse peak position; and 7 bits representing a pulse peak value. The pulse intensity represents the sum or integral of all discrete sample amplitude values of a detected pulse, or the discrete version of the area under the curve of the pulse as shown. That is, pulse intensity represents the total amount of energy of the light pulse detected. For example, if a pulse is detected with seven discrete samples at 1 ns sampling rate, the pulse intensity would be the sum value of all seven discrete sample values of detected amplitude. A sample of a pulse is only considered detected when the sample amplitude value is above a predetermined threshold. If the sampled amplitude values are clipped by a maximum amplitude range of the receiver 330, the system 300 extrapolates the pulse intensity based on all the sample values. As described below, the output data may include the pulse width and pulse intensity data, but removing some of the other data in raw data. The removed data may not have an impact, or have little impact, on the downstream processing, and therefore may not be needed.

With continued reference to FIG. 4A, time synchronization data 408 represent the difference between a system clock time and an external real world clock time. For example, data 408 can be generated based on system clock 360 and external clock signal 364, as shown in FIG. 3B. Since system clock 360 resets when LiDAR system 300 is powered off, this time synchronization data 408 is used to give a real world time reference to the output data stream. The time synchronization data 408 is only encoded very sparsely in the output data stream and near the beginning of each data stream. It does not require very frequent update.

In some examples, time synchronization data 408 includes 16 bytes (i.e., 128 bits), where four (4) bits of a data type identification segment represent the data type and four (4) bits of a sub-type segment represent a sub-type. The data type bits and sub-type bits are number values used to indicate each type and each sub-type. In some examples, the time synchronization data 408 may include a data type of 0 represented in binary bits (i.e., “0000”) indicating that this data set is the type of time synchronization data. The different sub-types may use different sub-type bits. If sub-type is represented by 0 in binary bits (i.e., “0000”), it indicates the data set is represented using precision time protocol (ptp). The time synchronization data 408 may include a sub-type of 1 represented in binary bits (i.e., “0001”) for network time protocol (ntp) or a sub-type of 15 (“1111”) for Global Positioning System (GPS) time stamp. GPS reference time is referenced to UTC with zero point defined as midnight on the night of Jan. 5, 1980. The time stamp comprises the number of weeks since that zero point and the number of seconds since the last week number change (0 to 604,799). Time synchronization data 408 also includes data used for hardware time and synchronized time. These data are represented using 78 bits in a synchronization and hardware time data segment. The time synchronization data 408 is used both internally by the encoder compression engine 389 and sent externally. Internally, it can be used to generate time stamps in the compressed data stream. Externally, it can be used by a software model or algorithm of an external system to view and analyze the raw encoded data, which like the compressed data stream, can be recorded in point cloud data files.

FIG. 4B is an example of an output data block header format 426 used by the LiDAR system of FIGS. 3A-3B, in accordance with some embodiments. A LiDAR system (e.g., system 300) may include multiple channels (e.g., multiple transmitting channels and correspondingly multiple receiving channels). Each channel may use a corresponding transmission laser beam to scan the field-of-view (FOV). In some embodiments, multiple transmission beams can scan the FOV together, thereby increasing the scanning resolution and speed. In one embodiment, the LiDAR system includes four channels and the below description uses four channels as an example. It is understood that any number of channels can be used in the LiDAR system. As described above, the control circuitry configures the output data based on the raw data, trigger data, encoder data, and time synchronization data. The output data are in a compressed format including a data set for one baseline channel and differential channel data for one or more channels based upon the baseline channel. For example, if there are four channels, the first channel may be the baseline channel, and the data for the other three channels can be differential channel data referencing the first channel. In some examples, the compressed output data are provided to a software algorithm or model of an internal or external system for further processing.

The LiDAR system, via the control circuitry, sends the output data in a data stream comprising blocks of data. The output data are also referred to as the point cloud data. In some examples, each block corresponds to one laser firing and contains received data points from all four channels. A block starts with a block header followed by information for the data points. The representation of point cloud uses a spherical coordinate system. As shown by the output data block header format 426 in FIG. 4B, the block header of the output data has 17 bytes and comprises four channel angle data segments, a time stamp segment, an index scan line segment, a block index segment, an ROI segment, a polygon mirror facet segment, and a reserved segment. The block header encodes angle data for all four channels (e.g., laser scanning angles or the angular positions of the mirrors in the steering mechanism) and other data that are relevant to the whole block. For example, the unit for the angle data is π/32768, where π is the ratio of the circumference of any circle to the diameter of that circle. Out of the 17 bytes (i.e., 136 bits), 2 bytes are used for channel 0 horizontal angle (e.g., azimuthal angle, with the zero angle position located at the straight forward direction) and 2 bytes are used for channel 0 vertical angle (e.g., polar angle, with the zero angle position located at straight forward direction). Channel 0's horizontal and vertical angles are stored in the baseline channel horizontal and vertical angle data segments in the block header. Both zero angle positions for azimuthal angle and polar angle are located at the straight forward direction. The zero angle positions can represent some other arbitrary angles, and in some examples, the zero angle positions may not be 100% accurate. The zero angle positions are roughly calibrated in the LiDAR system during manufacturing, and should not generally deviate over time. The straight forward direction is used as zero angle positions for both vertical and horizontal positions, allowing the least number of bits to be used to represent any angle in the FoV. This efficient result occurs because the straight forward direction is also the approximate middle of the FoV, with the least amount of angle difference to any extreme corners and edges of the FoV.

In a four-channel configuration, the other three channel angles are encoded as the differences with respect to channel 0's angles. The actual horizontal angle is the difference plus channel 0's horizontal angle. Vertical angles have a non-zero offset so that the actual vertical angle is the difference plus channel 0's vertical angle and the non-zero offset. The offset values used for channel 1/2/3 may be different. The differences for the other three channels' angle data are stored in the corresponding channel horizontal and vertical angle data segments in the block header. The underlying reason for encoding angles in this way is to use the least number of bits to represent angles. For example, with this differential encoding method, channel 1 uses 9 bits for horizontal angle difference and 8 bits for vertical angle difference. Channel 2 uses 10 bits for horizontal angle difference and 9 bits for vertical angle difference. Channel 3 uses 11 bits for horizontal angle difference and 9 bits for vertical angle difference. Thus, encoding the angles in this manner effectively compresses the number of bits needed to encode angles of 4 channels significantly, because 3 of the 4 channel's angles are encoded as difference values from channel 0. This format for the output data is efficient without sacrificing angle resolution. It is understood that more channels may be included in a LiDAR system (e.g., 6, 8, 12, . . . 64, etc.). The differential encoding method can be used for any number of channels, and the compression can be even more significant when the number of channels increases.

Further, the block header of output data shown in FIG. 4B may comprises other data segments for representing various information related to the LiDAR scanning. A LiDAR system can perform point scanning or line scanning. A frame in the point cloud data includes multiple scan lines (e.g., 20,000), each scan line may include many data points representing the detected light pulses formed by objects in the FOV. A block in the output data stream may corresponds to one or more data points of a scanline. Thus, in one embodiment, the block header of output data further comprises two bytes (i.e., 16 bits) used for a time stamp segment representing the timestamp relative to the beginning of the current frame of the associated block. Nine bits are used for the index of the scan line, to which the current block belongs. Two bytes (i.e., 16 bits) are used for the index of the block in the current scan line. Two bits are used to indicates region of interest (ROI) in the scanning. Three bits are used to represent the current polygon facet that produces the scanline. Two bits are for reservation. In an example implementation, the block header format may include 16 bits for channel_0_horizontal_angle; 16 bits for channel_0_vertical_angle; 16 bits for timestamp; 16 bits for block_index_in_scanline; 9 bits for scanline_index; 9 bits for horizontal_angle_diff_channel_1; 10 bits for horizontal_angle_diff_channel_2; 11 bits for horizontal_angle_diff_channel 3; 8 bits for vertical_angle_diff_channel_1; 9 bits for vertical_angle_diff_channel_2; 9 bits for vertical_angle_diff_channel_3; 2 bits for ROI; 3 bits facet_number; and 2 bits are reserved.

Comparing FIGS. 4A and 4B, the block header in the compressed output data block header format 426 uses a significantly smaller number of bits or bytes to include the same or similar amount of information as in the uncompressed data. For example, in the compressed block header format 426, the block header uses total of 88 bites (or 11 bytes) to represent the channel angular position data (both horizontal and vertical), while in the uncompressed format of the encoder data 404, the angular positions of the mirrors (galvanometer mirror for vertical scanning and polygon mirror for horizontal scanning) need a total of 156 bits (or about 19-20 bytes) for represent the angular position data. Thus, the compressed format 426 of the output data significantly reduced the number of bits to represent the same angular position data. The savings are enabled at least by using the differential channel encoding, rather than by using absolute angular positions for each channel.

Following the 17 bytes block header as illustrated by the output data block header format 426 in FIG. 4B, the output data further includes data points representing the detected data. Referring to FIG. 4D, each data point is defined by four (4) bytes. Out of the 4 bytes (i.e., 32 bits), 17 bits are used for the radius or the distance of the object associated with the data point from the LiDAR system (e.g., the unit is 0.005 meter); 9 bits are used for the pulse intensity or reflectance (e.g., the return light pulse intensity or reflectance, which depends on the distance and characteristics of the object reflecting the light back to the LiDAR system); 2 bits are used for the point type (e.g., data type indicating the data is detection data or pulse data); and 4 bits are used for the pulse elongation/width of the received pulse corresponding to the current point. The distance of the object for the data point is represented in radius using a spherical coordinate system rather than pulse time, resulting in extra savings of the number of bits needed. Further the pulse peak value and pulse peak position data can be removed (or sometime derived from the other pulse data), because they may not be very relevant for downstream processing using the point cloud data. Thus, the output data point format 428 may no longer include these information, resulting in further reducing of the number of bits. In one example, raw data 406 encodes 1 channel at a time. And it also requires the trigger data 402 and the encoder data 404, to calculate all of the timing for Time of flight (ToF) calculation of the angles and reflectance of detected object, etc. For raw data 406 to encode 4 points detected, there are a minimum of 42 bytes of data (e.g., 2+16+24 bytes). In comparison, for the compressed data, it has the output data block header 426 and the data point 428. Each block header encodes 4 possible points. Therefore, there are 4×4 bytes following 17 bytes of block header. The total number of bytes is 23 bytes of data for encoding 4 points detected. As can be seen, before compression, 42 bytes of raw data are needed for encoding 4 data points; while after compression, only 23 bytes are needed for encoding the same 4 points detected.

In some embodiments, the number of data points in a block can be a variable. For example, the block may comprise four data points, when each channel outputs at most 1 point in each laser firing. In the alternative, the block may comprise eight points, when each channel outputs at most 2 points during each laser firing. In an example implementation, the data point format 428 includes 17 bits for radius; 9 bits for intensity/reflectance; 2 bits for point type; and 4 bits for pulse elongation/width.

Overall, by eliminating unnecessary data and/or compressing data (e.g., using differential encoding), the embodiments of the present disclosure significantly reduce the number of bits required for the output data. In turn, this reduces the amount of data to be processed downstream and to be communicated to other systems. As a result, the embodiments of the present disclosure reduce the communication bandwidth requirements, reduce the processing power, and improve the computing efficiency.

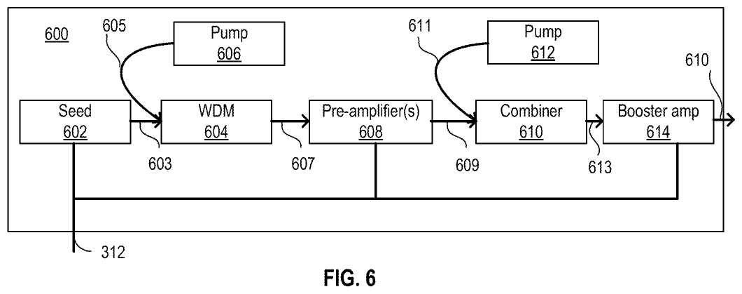

FIG. 5 is a flow diagram of method 500 for data encoding and compression of a LiDAR system of FIGS. 3A-3B, in accordance with some embodiments. Method 500 of data encoding and compression within a LiDAR system begins in action 502. After a return light pulse is reflected by an object in the FOV in an action 504, method 500 includes receiving detection data from an optical detector of the scanning system, wherein the detection data is associated with the return light pulse. In an action 506, method 500 includes receiving encoder data from an optical steering system, wherein the encoder data is generated by position encoders associated with the optical steering system. In an action 508, method 500 includes decoding the detection data into raw data. The raw data format is described above in connection with FIG. 4A. Method 500 also includes configuring output data from the raw data, trigger data, encoder data, and time synchronization data, wherein the output data have a compressed format including a full data set for one baseline channel and differential channel data for one or more channels based upon the baseline channel in an action 512. In one example, the compressed format of the output data includes a data set of one baseline channel data encoded using absolute angle positions and one or more data sets of additional channels data encoded using differential angle positions with respect to the absolute angle positions of the baseline channel. In some embodiments, the output data is further processed and sent in blocks, wherein each block corresponds to one laser firing and contains received data points from each one of the one or more channels.

In some examples, the output data starts with a block header followed by information for the data points of the point cloud. Representation of point cloud output data may comprise the use of a spherical coordinate system. Although not shown, method 500 of data encoding and compression within a LiDAR system may include transmitting the trigger data to one or more sources of light to control emission timing of the one or more beams of light. Method 500 may also include receiving the encoder data from the optical steering mechanism, wherein the encoder data are generated by position encoders of the galvanometer mirror and the polygon mirror. In some embodiments, the output data and the time synchronization data can be transmitted to external sources for further data processing. Method 500 may also include other actions described in this disclosure.

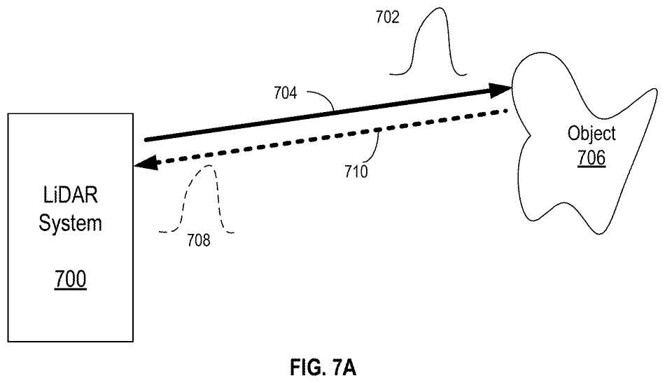

FIG. 6 is a block diagram illustrating an example fiber-based laser source 600 having a seed laser and one or more pumps (e.g., laser diodes) for pumping desired output power. Fiber-based laser source 600 is an example of light source 310 depicted in FIG. 3A. In some embodiments, fiber-based laser source 600 comprises a seed laser 602 to generate initial light pulses of one or more wavelengths (e.g., infrared wavelengths such as 1550 nm), which are provided to a wavelength-division multiplexor (WDM) 604 via an optical fiber 603. Fiber-based laser source 600 further comprises a pump 606 for providing laser power (e.g., of a different wavelength, such as 980 nm) to WDM 604 via an optical fiber 605. WDM 604 multiplexes the light pulses provided by seed laser 602 and the laser power provided by pump 606 onto a single optical fiber 607. The output of WDM 604 can then be provided to one or more pre-amplifier(s) 608 via optical fiber 607. Pre-amplifier(s) 608 can be optical amplifier(s) that amplify optical signals (e.g., with about 10-30 dB gain). In some embodiments, pre-amplifier(s) 608 are low noise amplifiers. Pre-amplifier(s) 608 output to an optical combiner 610 via an optical fiber 609. Combiner 610 combines the output laser light of pre-amplifier(s) 608 with the laser power provided by pump 612 via an optical fiber 611. Combiner 610 can combine optical signals having the same wavelength or different wavelengths. One example of a combiner is a WDM. Combiner 610 provides combined optical signals to a booster amplifier 614, which produces output light pulses via optical fiber 610. The booster amplifier 614 provides further amplification of the optical signals (e.g., another 20-40 dB). The outputted light pulses can then be transmitted to transmitter 320 and/or optical steering mechanism 340 (shown in FIG. 3A). It is understood that FIG. 6 illustrates one example configuration of fiber-based laser source 600. Laser source 600 can have many other configurations using different combinations of one or more components shown in FIG. 6 and/or other components not shown in FIG. 6 (e.g., other components such as power supplies, lens(es), filters, splitters, combiners, etc.).

In some variations, fiber-based laser source 600 can be controlled (e.g., by control circuitry 350) to produce pulses of different amplitudes based on the fiber gain profile of the fiber used in fiber-based laser source 600. Communication path 312 couples fiber-based laser source 600 to control circuitry 350 (shown in FIG. 3) so that components of fiber-based laser source 600 can be controlled by or otherwise communicate with control circuitry 350. Alternatively, fiber-based laser source 600 may include its own dedicated controller. Instead of control circuitry 350 communicating directly with components of fiber-based laser source 600, a dedicated controller of fiber-based laser source 600 communicates with control circuitry 350 and controls and/or communicates with the components of fiber-based laser source 600. Fiber-based laser source 600 can also include other components not shown, such as one or more power connectors, power supplies, and/or power lines.

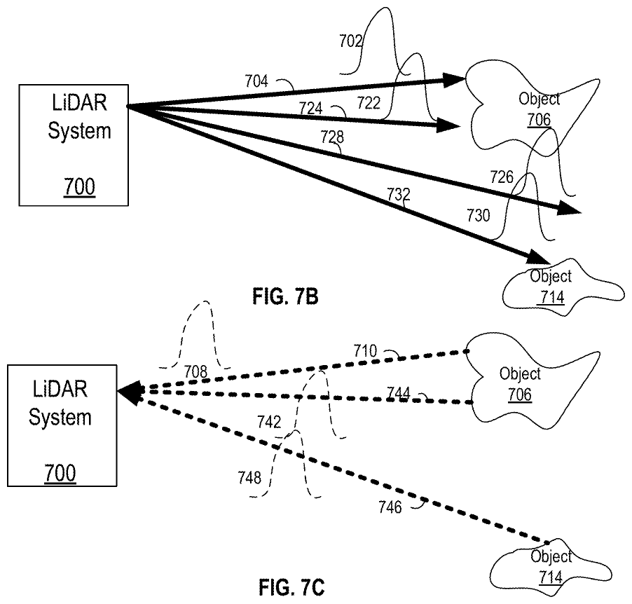

As described above, some LiDAR systems use the time-of-flight (ToF) of light signals (e.g., light pulses) to determine the distance to objects in a light path. For example, with reference to FIG. 7A, an example LiDAR system 700 includes a laser light source (e.g., a fiber laser), an optical steering mechanism (e.g., a system of one or more moving mirrors), and a light detector (e.g., a photodetector with one or more optics). LiDAR system 700 can be implemented using, for example, LiDAR system 300 described above. LiDAR system 700 transmits a light pulse 702 along light path 704 as determined by the optical steering mechanism of LiDAR system 700. In the depicted example, light pulse 702, which is generated by the laser light source, is a short pulse of laser light. Further, the signal steering mechanism of the LiDAR system 700 is a pulsed-signal steering mechanism. However, it should be appreciated that LiDAR systems can operate by generating, transmitting, and detecting light signals that are not pulsed and derive ranges to an object in the surrounding environment using techniques other than time-of-flight. For example, some LiDAR systems use frequency modulated continuous waves (i.e., “FMCW”). It should be further appreciated that any of the techniques described herein with respect to time-of-flight based systems that use pulsed signals also may be applicable to LiDAR systems that do not use one or both of these techniques.

Referring back to FIG. 7A (e.g., illustrating a time-of-flight LiDAR system that uses light pulses), when light pulse 702 reaches object 706, light pulse 702 scatters or reflects to form a return light pulse 708. Return light pulse 708 may return to system 700 along light path 710. The time from when transmitted light pulse 702 leaves LiDAR system 700 to when return light pulse 708 arrives back at LiDAR system 700 can be measured (e.g., by a processor or other electronics, such as control circuitry 350, within the LiDAR system). This time-of-flight combined with the knowledge of the speed of light can be used to determine the range/distance from LiDAR system 700 to the portion of object 706 where light pulse 702 scattered or reflected.

By directing many light pulses, as depicted in FIG. 7B, LiDAR system 700 scans the external environment (e.g., by directing light pulses 702, 722, 726, 730 along light paths 704, 724, 728, 732, respectively). As depicted in FIG. 7C, LiDAR system 700 receives return light pulses 708, 742, 748 (which correspond to transmitted light pulses 702, 722, 730, respectively). Return light pulses 708, 742, and 748 are formed by scattering or reflecting the transmitted light pulses by one of objects 706 and 714. Return light pulses 708, 742, and 748 may return to LiDAR system 700 along light paths 710, 744, and 746, respectively. Based on the direction of the transmitted light pulses (as determined by LiDAR system 700) as well as the calculated range from LiDAR system 700 to the portion of objects that scatter or reflect the light pulses (e.g., the portions of objects 706 and 714), the external environment within the detectable range (e.g., the field of view between path 704 and 732, inclusively) can be precisely mapped or plotted (e.g., by generating a 3D point cloud or images).

If a corresponding light pulse is not received for a particular transmitted light pulse, then LiDAR system 700 may determine that there are no objects within a detectable range of LiDAR system 700 (e.g., an object is beyond the maximum scanning distance of LiDAR system 700). For example, in FIG. 7B, light pulse 726 may not have a corresponding return light pulse (as illustrated in FIG. 7C) because light pulse 726 may not produce a scattering event along its transmission path 728 within the predetermined detection range. LiDAR system 700, or an external system in communication with LiDAR system 700 (e.g., a cloud system or service), can interpret the lack of return light pulse as no object being disposed along light path 728 within the detectable range of LiDAR system 700.

In FIG. 7B, light pulses 702, 722, 726, and 730 can be transmitted in any order, serially, in parallel, or based on other timings with respect to each other. Additionally, while FIG. 7B depicts transmitted light pulses as being directed in one dimension or one plane (e.g., the plane of the paper), LiDAR system 700 can also direct transmitted light pulses along other dimension(s) or plane(s). For example, LiDAR system 700 can also direct transmitted light pulses in a dimension or plane that is perpendicular to the dimension or plane shown in FIG. 7B, thereby forming a 2-dimensional transmission of the light pulses. This 2-dimensional transmission of the light pulses can be point-by-point, line-by-line, all at once, or in some other manner. That is, LiDAR system 700 can be configured to perform a point scan, a line scan, a one-shot without scanning, or a combination thereof. A point cloud or image from a 1-dimensional transmission of light pulses (e.g., a single horizontal line) can generate 2-dimensional data (e.g., (1) data from the horizontal transmission direction and (2) the range or distance to objects). Similarly, a point cloud or image from a 2-dimensional transmission of light pulses can generate 3-dimensional data (e.g., (1) data from the horizontal transmission direction, (2) data from the vertical transmission direction, and (3) the range or distance to objects). In general, a LiDAR system performing an n-dimensional transmission of light pulses generates (n+1) dimensional data. This is because the LiDAR system can measure the depth of an object or the range/distance to the object, which provides the extra dimension of data. Therefore, a 2D scanning by a LiDAR system can generate a 3D point cloud for mapping the external environment of the LiDAR system.

The density of a point cloud refers to the number of measurements (data points) per area performed by the LiDAR system. A point cloud density relates to the LiDAR scanning resolution. Typically, a larger point cloud density, and therefore a higher resolution, is desired at least for the region of interest (ROI). The density of points in a point cloud or image generated by a LiDAR system is equal to the number of pulses divided by the field of view. In some embodiments, the field of view can be fixed. Therefore, to increase the density of points generated by one set of transmission-receiving optics (or transceiver optics), the LiDAR system may need to generate a pulse more frequently. In other words, a light source in the LiDAR system may have a higher pulse repetition rate (PRR). On the other hand, by generating and transmitting pulses more frequently, the farthest distance that the LiDAR system can detect may be limited. For example, if a return signal from a distant object is received after the system transmits the next pulse, the return signals may be detected in a different order than the order in which the corresponding signals are transmitted, thereby causing ambiguity if the system cannot correctly correlate the return signals with the transmitted signals.

To illustrate, consider an example LiDAR system that can transmit laser pulses with a pulse repetition rate between 500 kHz and 1 MHz. Based on the time it takes for a pulse to return to the LiDAR system and to avoid mix-up of return pulses from consecutive pulses in a typical LiDAR design, the farthest distance the LiDAR system can detect may be 300 meters and 150 meters for 500 kHz and 1 MHz, respectively. The density of points of a LiDAR system with 500 kHz repetition rate is half of that with 1 MHz. Thus, this example demonstrates that, if the system cannot correctly correlate return signals that arrive out of order, increasing the repetition rate from 500 kHz to 1 MHz (and thus improving the density of points of the system) may reduce the detection range of the system. Various techniques are used to mitigate the tradeoff between higher PRR and limited detection range. For example, multiple wavelengths can be used for detecting objects in different ranges. Optical and/or signal processing techniques (e.g., pulse encoding techniques) are also used to correlate between transmitted and return light signals.

Various systems, apparatus, and methods described herein may be implemented using digital circuitry, or using one or more computers using well-known computer processors, memory units, storage devices, computer software, and other components. Typically, a computer includes a processor for executing instructions and one or more memories for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of encoding and compression of point cloud data of FIG. 5, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

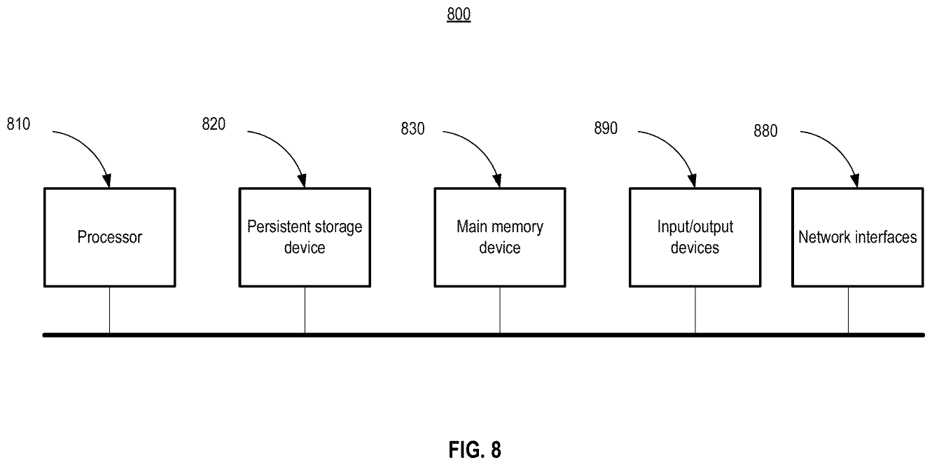

A high-level block diagram of an example apparatus that may be used to implement systems, apparatus and methods described herein is illustrated in FIG. 8. Apparatus 800 comprises a processor 810 operatively coupled to a persistent storage device 820 and a main memory device 830. Processor 810 controls the overall operation of apparatus 800 by executing computer program instructions that define such operations. The computer program instructions may be stored in persistent storage device 820, or other computer-readable medium, and loaded into main memory device 830 when execution of the computer program instructions is desired. For example, processor 810 may be used to implement one or more components and systems described herein, such as control circuitry 350 (shown in FIG. 3), vehicle perception and planning system 220 (shown in FIG. 2), and vehicle control system 280 (shown in FIG. 2). Thus, the method steps of encoding and compression of point cloud data of FIG. 5 can be defined by the computer program instructions stored in main memory device 830 and/or persistent storage device 820 and controlled by processor 810 executing the computer program instructions. For example, the computer program instructions can be implemented as computer executable code programmed by one skilled in the art to perform an algorithm defined by the method steps discussed herein in connection with FIG. 5. Accordingly, by executing the computer program instructions, the processor 810 executes an algorithm defined by the method steps of these in the aforementioned figure. Apparatus 800 also includes one or more network interfaces 880 for communicating with other devices via a network. Apparatus 800 may also include one or more input/output devices 890 that enable user interaction with apparatus 800 (e.g., display, keyboard, mouse, speakers, buttons, etc.).

Processor 810 may include both general and special purpose microprocessors and may be the sole processor or one of multiple processors of apparatus 800. Processor 810 may comprise one or more central processing units (CPUs), and one or more graphics processing units (GPUs), which, for example, may work separately from and/or multi-task with one or more CPUs to accelerate processing, e.g., for various image processing applications described herein. Processor 810, persistent storage device 820, and/or main memory device 830 may include, be supplemented by, or incorporated in, one or more application-specific integrated circuits (ASICs) and/or one or more field programmable gate arrays (FPGAs).

Persistent storage device 820 and main memory device 830 each comprise a tangible non-transitory computer readable storage medium. Persistent storage device 820, and main memory device 830, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices, semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices.

Input/output devices 890 may include peripherals, such as a printer, scanner, display screen, etc. For example, input/output devices 890 may include a display device such as a cathode ray tube (CRT), plasma or liquid crystal display (LCD) monitor for displaying information to a user, a keyboard, and a pointing device such as a mouse or a trackball by which the user can provide input to apparatus 800.

Any or all of the functions of the systems and apparatuses discussed herein may be performed by processor 810, and/or incorporated in, an apparatus or a system such as LiDAR system 300. Further, LiDAR system 300 and/or apparatus 800 may utilize one or more neural networks or other deep-learning techniques performed by processor 810 or other systems or apparatuses discussed herein.

One skilled in the art will recognize that an implementation of an actual computer or computer system may have other structures and may contain other components as well, and that FIG. 8 is a high-level representation of some of the components of such a computer for illustrative purposes.

The foregoing specification is to be understood as being in every respect illustrative and exemplary, but not restrictive, and the scope of the invention disclosed herein is not to be determined from the specification, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. Those skilled in the art could implement various other feature combinations without departing from the scope and spirit of the invention.

What is claimed is:

1. A Light Detection and Ranging (LiDAR) system having data encoding and compression, comprising:
a laser source couples to supply a plurality of light pulses to an optical steering system, wherein the optical steering system directs the plurality of light pulses in accordance with a field of view (FOV);
an optical detector coupled to receive return light pulses of one or more objects in the respective path of one or more of the plurality of light pulses within the FOV to generate detection data; and
an encoder/decoder processing agent coupled to transform detection data into raw data and to configure output data based on the raw data, trigger data, encoder data, and time synchronization data, and wherein the output data are in a compressed format including a data set of one baseline channel data encoded using absolute angle positions and one or more data sets of additional channels data encoded using differential angle positions with respect to the absolute angle positions of the baseline channel;
wherein the optical steering system couples to provide the encoder data generated by position encoders.

2. The LiDAR scanning system of claim 1, further comprises:
a controller coupled to receive data from the encoder/decoder processing agent, wherein the controller is coupled to the optical steering system and the laser source to coordinate movement speed of the mirror motor galvanometer and the rotatable polygon mirror with the plurality of light pulses supplied by the laser source.

3. The LiDAR scanning system of claim 1, wherein the encoder/decoder processing agent comprises a data pre-processor configured to generate the trigger data, the trigger data comprising:
a data type identification segment; and
a trigger time stamp segment.

4. The LiDAR scanning system of claim 1, wherein the data pre-processor is configured to generate the trigger data based on a system clock internal to the LiDAR system.

5. The LiDAR scanning system of claim 1, wherein the optical steering system comprises a mirror motor galvanometer for vertical scanning and a rotatable polygon mirror for horizontal scanning.

6. The LiDAR scanning system of claim 5, wherein the optical wherein the encoder data comprises:
a time stamp segment representing absolute time data based on a system clock of the LiDAR system;
a polygon encoder segment appended on the time stamp segment, the polygon encoder segment comprising angle positions of the rotatable polygon mirror; and
a galvanometer encoder segment appended on the polygon encoder segment, the galvanometer encoder segment comprising angle positions of the mirror motor galvanometer.

7. The LiDAR scanning system of claim 1, wherein the raw data comprises:
a data type identification segment, wherein a data type value in the data type identification segment identifies a channel of a plurality of channels of the LiDAR system;
a first pulse time segment appended to the data type identification segment;
a second pulse time segment appended to the first pulse time segment, wherein data values in a combination of the first pulse time segment and the second pulse time segment represent a timestamp associated with detection of a return light pulse;
a pulse intensity segment appended to the second pulse time segment, wherein a data value in the pulse intensity segment represents an amplitude of the return light pulse; and
a pulse width segment appended to the pulse intensity segment, wherein a data value in the pulse width segment represents a pulse width of the return light pulse.

8. The LiDAR scanning system of claim 1, wherein the time synchronization data comprises one or more segments, the time synchronization data representing differences between a system clock internal to the LiDAR system and an external clock time.

9. The LiDAR scanning system of claim 1, wherein the data set of the baseline channel data of the output data comprises:
a first horizontal angle data segment encoding absolute polygon angle positions;
a first vertical angle data segment appended to the first horizontal angle data segment, the first vertical angle data segment encoding absolute galvanometer angle positions;
wherein the one or more data sets of the additional channels data of the output data comprise:
one or more additional horizontal angle data segments encoding differential polygon angle positions with respect to the absolute polygon angle positions of the first horizontal angle data segment;
one or more additional vertical angle data segments appended to the one or more additional horizontal angle data segments, the one or more additional vertical angle data segments encoding differential galvanometer angle positions with respect to the absolute galvanometer angle positions of the first vertical angle data segment; and
a time stamp segment appended to the one or more additional vertical angle data segments, wherein a data value in the time stamp segment represents a time relative to a beginning of a current frame a block of the output data.

10. The LiDAR scanning system of claim 1, wherein the encoder/decoder processing agent comprises:
a receiver couples to receive data associated with the return light signals from the optical detector, wherein the receiver facilities generating the raw data; and
an encoder/decoder engine coupled to the receiver to decode the data associated with the return light signals and to compress the data for configuring the output data.

11. The LiDAR scanning system of claim 10, wherein the encoder/decoder processing agent further comprising:
a data pre-processor coupled to the receiver and configured to perform data filtering and initial encoding.

12. The LiDAR scanning system of claim 10, wherein the encoder/decoder engine comprises:
a decoder; and
an encoder compression engine coupled to the decoder, the encoder compression engine being configured to configure the output data in a compressed format.

13. The LiDAR scanning system of claim 1, further comprising a controller that comprises:
a laser controller configured to control the laser source;
a galvanometer controller configured to control the mirror motor galvanometer based on the encoder data; and
a polygon controller configured to control the rotatable polygon mirror based on the encoder data.

14. A method of performing data encoding and compression for a Light Detection and Ranging (LiDAR) scanning system, comprising:
receiving detection data from an optical detector of the LiDAR scanning system, wherein the detection data is associated with return light pulses reflected by one or more objects in the FOV;
receiving encoder data from an optical steering system, wherein the encoder data are generated by position encoders associated with the optical steering system;
decoding the detection data into raw data; and
configuring output data from the raw data, trigger data, the encoder data, and time synchronization data,
wherein the output data are in a compressed format including a data set of one baseline channel data encoded using absolute angle positions and one or more data sets of additional channels data encoded using differential angle positions with respect to the absolute angle positions of the baseline channel.

15. The method of claim 14, further comprising:
steering one or more beams of light using a plurality of reflective facets of a polygon mirror to scan a Field-Of-View (FOV) in a first direction; and
steering the one or more beams of light using a galvanometer mirror to scan the FOV in a second direction.

16. The method of claim 14, wherein the configuring output data in a compressed format comprises,
identifying the baseline channel;
receiving the data set of the baseline channel data encoded using absolute angle positions;
determining, for each of one or more additional channels, the differential angle positions with respect to the absolute angle positions of the baseline channel;
constructing a plurality of block headers of the output data based on the data set of the baseline channel and the one or more data sets of the additional channels data; and
appending, to the block headers, one or more other data to form the output data.

17. The method of claim 16, wherein the data corresponding to the based channel are encoded using absolute horizontal angle positions and absolute vertical angle positions.

18. The method of claim 16, wherein determining, for each of one or more additional channels, the differential angle positions with respect to the absolute angle positions of the baseline channel comprises:
obtaining absolute angle positions associated with the one or more additional channels; and
determining the differential angle positions based on the absolute angle positions associated with the one or more additional channels and the absolute angle positions of the baseline channel.

19. The method of claim 16, wherein the data set of the baseline channel data comprises:
a first horizontal angle data segment encoding absolute polygon angle positions;
a first vertical angle data segment appended to the first horizontal angle data segment, the first vertical angle data segment encoding absolute galvanometer angle positions;
wherein the one or more data sets of the additional channels data of the output data comprise:
one or more additional horizontal angle data segments encoding differential polygon angle positions with respect to the absolute polygon angle positions of the first horizontal angle data segment;
one or more additional vertical angle data segments appended to the one or more additional horizontal angle data segments, the one or more additional vertical angle data segments encoding differential galvanometer angle positions with respect to the absolute galvanometer angle positions of the first vertical angle data segment; and
a time stamp segment appended to the one or more additional vertical angle data segments, wherein a data value in the time stamp segment represents a time relative to a beginning of a current frame a block of the output data.

20. A non-transitory computer-readable medium including instructions for performing a method of data encoding and compression for a Light Detection and Ranging (LiDAR) scanning system comprising one or more processors and memory, the instruction being stored in the memory, when executed, causing the one or more processors to perform:
receiving detection data associated from an optical detector of the LiDAR scanning system, wherein the detection data is associated with return light pulses reflected by one or more objects in the FOV;
receiving encoder data from an optical steering system, wherein the encoder data are generated by position encoders associated with the optical steering system;
decoding the detection data into raw data;
generating output data from the raw data, trigger data, encoder data, and time synchronization data, wherein the output data are in a compressed format including a data set of one baseline channel data encoded using absolute angle positions and one or more data sets of additional channels data encoded using differential angle positions with respect to the absolute angle positions of the baseline channel; and
receiving the encoder data from the optical steering system, wherein the encoder data are generated by position encoders of the galvanometer mirror and the polygon mirror.
